(19) United States
(12) Patent Application Publication
(10) Pub. No.: US 2005/0237071 A1
(43) Pub. Date: Oct. 27, 2005

(54) Electronic component test apparatus

(75) Inventors: Akihiko Ito, Tokyo (JP); Hiroto Nakamura, Tokyo (JP)

Correspondence Address: BIRCH STEWART KOLASCH & BIRCH, PO BOX 747, FALLS CHURCH, VA, 22040-0747, US

(73) Assignee: ADVANTEST Corporation, Tokyo (JP)

(21) Appl. No.: 10/512,051

(22) PCT Filed: Apr. 25, 2002
(86) PCT No.: PCT/JP02/04124

§ 371 Date: Nov. 10, 2004

(51) Int. Cl. G01R 31/02

(52) U.S. Cl. 324/754

(57) ABSTRACT

An electronic device testing apparatus for conducting a test by pressing input/output terminals of electronic devices to be tested against contact portions of a test head portion (100) while loading the electronic devices to be tested on electronic device conveying media (11, 12, 13, 14) by a moving means: wherein two electronic device conveying media (11, 12) loaded with electronic devices to be tested are gripped by one moving means and two electronic device conveying media (13, 14) loaded with electronic devices to be tested are gripped by the other moving means at a time, and the respective moving means independently conveys to and from the contact groups.

### TECHNICAL FIELD

The present invention relates to an electronic device testing apparatus for testing an electronic device, and an electronic device testing apparatus capable of conducting a test with a high testing efficiency due to provision of a plurality of moving means for conducting a test by gripping a plurality of electronic device conveying media loaded with electronic devices to be tested at a time.

### BACKGOUND ART

In an electronic device testing apparatus called a handler, a large number of electronic devices held on a tray are conveyed into the electronic device testing apparatus, and the respective electronic devices are brought to electronically contact a test head for conducting a test by an electronic device testing apparatus body (hereinafter, also referred to as a tester). When the test is finished, the electronic devices are taken out from the test head and reloaded to trays in accordance with the test results so as to be classified to categories of good ones and defective ones, etc.

In conventional electronic device testing apparatuses, there is a type wherein a tray for holding pre-test electronic devices or holding post-tested electronic devices (hereinafter, also referred to as a customer tray) differs from a tray conveyed by circulating inside the electronic device testing apparatus (hereinafter, also referred to as a test tray). In an electronic device testing apparatus of this kind, electronic devices are reloaded between the customer tray and the test tray before and after the test, and the electronic devices are pressed against a test head in a state of being carried on the test tray in a test step for conducting a test by bringing the electronic devices to contact the test head.

On the other hand, there is known a type wherein electronic devices held on a customer tray are applied with a thermal stress by using a heat plate, etc., then, some of them are picked up by suction heads at a time, conveyed to a test head, and brought to electronically contact. In a test step of an electronic device testing apparatus of this kind, electronic devices are pressed against the test head in a state of being picked up by the suction heads.

When being pressed, a large number of contact portions are provided to the test head (Normally, the number of test positions capable of measuring at a time, that is, the simultaneously measured number is limited to 2ⁿ, such as 32 or 64, per one electronic device testing apparatus. Note that “n” is a natural number), and by conducting tests on a large number of electronic devices at a time, tests with high throughput are conducted.

Conventionally, when conducting tests on electronic devices, the test has been conducted in a final step of production steps of the electronic devices, so that a test has been conducted on completed electronic devices after steps of molding and wire bonding, etc. are finished.

However, when judged to be defective by the test after finishing the production steps, steps up to the completion after becoming a state of being ready for the test may be wasted, so that it is preferable that the test is conducted when it became to be in the state of being ready for the test and the defectives are taken away at this stage.

In the production steps of electronic devices, as shown in FIG. 24, due to limitation of the nature of the electronic device, the electronic devices to be tested 20 are loaded on an electronic device conveying medium of strip formats 10, etc. (a strip format of four rows by eleven columns in the case of FIG. 24) for preventing the electronic devices 20 from parting for conveying within and between respective steps. Accordingly, to conduct a test on electronic devices 20 in a state it became ready for the test before reaching the final step, the test has to be conducted while the electronic devices 20 are loaded on the electronic device conveying medium 10, furthermore, the arrangement of the electronic devices 20 on the electronic device conveying medium 10 has to be kept to be conveyed to the next step. Note that there are arbitrary number and arrangement of the electronic devices to be tested 20 on the electronic device conveying medium 10.

Also, contact portions 110a of a test head of the conventional electronic device testing apparatus composed only one contact group 110 composed of the contact portions 110a by the simultaneously measured number limited in the electronic device testing apparatus as shown in FIG. 25 and FIG. 26. FIG. 25 shows one contact group 110 configured that the number of the contact portions 110a is limited to 32, and FIG. 26 shows one contact group 110 configured that the number of the contact portions 110a is limited to 64.

Therefore, for example as shown in FIG. 27, when securing test positions with the simultaneously measured number of 32 for the electronic devices to be tested 20 loaded on the electronic device conveying medium 10, it is possible to secure test positions of 32 in the first round test (Post-tested electronic devices 21 in FIG. 27 show all of 32 black squares in the figure), while only remaining 16 test positions can be secured in the second round test (Pre-test electronic devices 22 in FIG. 27 show all of 16 white squares in the figure). Thus, only half the number of the 32 contact portions is used in the second round test, so that there was a problem that the test efficiency declines.

For these problems, to always secure the simultaneously measured number of 32 regularly on the electronic device conveying medium 10, it is considered, for example, one contact group 110 composed of 32 contact portions 110a is divided to 32 contact groups, and 32 electronic device conveying media 10 are conveyed at a time to conduct a test on electronic devices to be tested 20 loaded on the electronic device conveying media 10 at a time. In this case, the apparatus is liable to be huge and complicated, so that it is more preferable to secure the simultaneously measured number with as few electronic device conveying media 10 as possible.

Alternately, for example, a method of dividing 32 contact portions 110a to some contact groups 110 and setting an independent moving means to each of the contact groups 110 is also considered to always secure a simultaneously measured number with as few electronic device conveying media 10 as possible. However, when the number of the contact groups exceeds a certain degree, it may cause an increase of facility costs.

Furthermore, for example, a method of dividing 32 contact portions 110a to some contact groups 110, collectively moving all electronic device conveying media 10 by one moving means, and providing a moving means for conducting a test may be also considered for always securing the simultaneously measured number. However, since a large number of electronic device conveying media 10 are collectively gripped, there arises a problem that the larger the number of electronic device conveying media 10, the more difficult it becomes to secure alignment accuracy of the respective electronic devices 20 and the contact portions 110a.

The present invention was made in consideration of the above problems of the prior art and has as an object thereof to provide an electronic device testing apparatus capable of conducting a test with a high test efficiency on electronic devices to be tested loaded on a plurality of electronic device conveying media by arbitrary number and in an arrangement thereof.

### DISCLOSURE OF THE INVENTION

To attain the above object, an electronic device testing apparatus of the present invention is an electronic device testing apparatus, for conducting a test by pressing input/output terminals of electronic devices to be tested against contact portions of a test head by a moving means while the electronic devices to be tested are loaded on an electronic device conveying medium, comprising one or a plurality of the moving means capable of gripping and conveying to and from the contact portions a plurality of the electronic device conveying media loaded with the electronic devices to be tested at a time.

In the electronic device testing apparatus of the present invention, a moving means is not provided independently to each of contact groups or a moving means for collectively gripping all contact groups is not provided, but a plurality of moving means capable of gripping a plurality of electronic device conveying media loaded with electronic devices to be tested at a time and conveying them to and from contact portions are provided, so that an increase of the facility cost and an expansion of the occupying area are suppressed, the simultaneously measured number is always secured while securing alignment accuracy, and a high testing efficiency can be realized.

Also, an electronic device testing apparatus of the present invention is an electronic device testing apparatus wherein the moving means is capable of freely selecting the gripping number within a number able to be gripped.

By suitably selecting the gripping number within the number able to be gripped by the moving means in accordance with an arbitrary number and arrangement of electronic devices to be tested on the electronic device conveying medium, the simultaneously measured number can be secured and a high testing efficiency can be realized.

Also, in the electronic device testing apparatus, the one moving means is capable of freely selecting the gripping number independently from other moving means.

By freely selecting the gripping number by the moving means on a test head and combining them among a plurality of moving means on the test head, a moving method can be flexibly matched to a production plan or other situation changes, the simultaneously measured number can be always secured, and flexible countermeasure becomes possible to realize a high testing efficiency.

Also, the any two or more moving means among the plurality of moving means have a substantially overlapping operation range on a contact group as a set of the contact portions.

Due to provision of any two or more moving means having an operation range substantially overlapping on a contact group as a set of contact portions, the respective moving means operate in turn for the contact group, so that a part of index time in one moving means can be absorbed in test time of other moving means.

Note that the test time indicates time from transmission of a start request signal to a contact portion wherein pre-test electronic devices on an electronic device conveying medium are set until an output of a test end signal after conducting a test. The index time indicates time from transmission of a test end signal from the contact portion till an output of a start request signal by the moving means after moving the electronic device conveying medium loaded with post-test electronic devices and setting pre-test electronic devices on the next electronic device conveying medium to the contact portion. Furthermore, a test rate is made up by a sum of the test time and the index time and is the shortest time from an output of a start request signal by the moving means till an output of the next request signal.

Particularly, when the test time is short, the ratio occupied by the index time in the test rate becomes large, so that high throughput can be realized by conducting tests on a range having a contact group by a plurality of moving means in turn.

The electronic device conveying medium in the present invention includes all media for loading electronic devices to be tested.

For example, in the electronic devices testing apparatus as set froth in claim 5, the electronic device conveying medium is a strip format or a wafer. When conducting a test on electronic devices on a wafer, a high testing efficiency is realized near the outer circumference where test positions by the simultaneously measured number are hard to be secured.

According to the above explained present invention, it becomes possible to optimally determine the optimal number of contact groups on a test head, the number and arrangement of contact portions in each contact group, and the number of independent moving means based on the number and arrangement of electronic devices to be tested on an electronic device conveying medium and a production plan, etc.; and it becomes possible to optimally determine a contact group corresponding to each moving device, the number of electronic device conveying media able to be gripped by each moving device, the freely gripped number of electronic device conveying media within the number able to be gripped by each moving device being independent from other moving devices. As a result, the simultaneously measured number can be always secured, and tests can be conducted with a high testing efficiency on electronic devices to be tested loaded on a plurality of electronic device conveying media.

### BRIEF DESCRIPTION OF DRAWINGS

FIG. 1 is a schematic view of a first embodiment of the present invention.

FIG. 2 is a view of a test head portion 100, detailed configuration around it and the control system of the first embodiment of the present invention.

FIG. 3 is a schematic view of corresponding relationship of an electronic device conveying medium and each contact group when conducting a test on electronic devices to be tested on one electronic device conveying medium in the simultaneously measured number of 32.

FIG. 4 is a view showing an arrangement of each contact group when conducting a test on electronic devices to be tested on one electronic device conveying medium in the simultaneously measured number of 32.

FIG. 5 is a view showing test positions in the first round of electronic devices to be tested arranged on an electronic device conveying medium when conducting a test on electronic devices to be tested on one electronic device conveying medium in the simultaneously measured number of 32.

FIG. 6 is a schematic view of corresponding relationship of an electronic device conveying medium and each contact group when conducting a test on electronic devices to be tested on two electronic device conveying media by using the same moving device in the simultaneously measured number of 32.

FIG. 7 is a view showing an arrangement of each contact group when conducting a test on electronic devices to be tested on two electronic device conveying media by using the same moving device in the simultaneously measured number of 32 by using the same moving device.

FIG. 8 is a view showing test positions in the first round of electronic devices to be tested arranged on electronic device conveying media when conducting a test on electronic devices to be tested on two electronic device conveying media by using the same moving device in the simultaneously measured number of 32.

FIG. 9 is a schematic view of corresponding relationship of electronic device conveying media and each contact group when conducting a test on electronic devices to be tested on two electronic device conveying media by using a different moving device in the simultaneously measured number of 32.

FIG. 10 is a view showing an arrangement of respective contact groups when conducting a test on electronic devices to be tested on two electronic device conveying media by using a different moving device in the simultaneously measured number of 32.

FIG. 11 is a view showing test positions in the first round of electronic devices to be tested arranged on electronic device conveying media when conducting a test on electronic devices to be tested on two electronic device conveying media by using a different moving device in the simultaneously measured number of 32.

FIG. 12 is a view showing corresponding relationship of electronic device conveying media and respective contact groups when conducting a test on electronic devices to be tested on three electronic device conveying media in the simultaneously measured number of 32.

FIG. 13 is a view showing arrangements of respective contact groups when conducting a test on electronic devices to be tested on three electronic device conveying media in the simultaneously measured number of 32.

FIG. 14 is a view showing test positions in the first round of electronic devices to be tested arranged on electronic device conveying media when conducting a test on electronic devices to be tested on three electronic device conveying media in the simultaneously measured number of 32.

FIG. 15 is a view showing corresponding relationship of electronic device conveying media and respective contact groups when conducting a test on electronic devices to be tested on four electronic device conveying media in the simultaneously measured number of 32.

FIG. 16 is a view showing arrangements of respective contact groups when conducting a test on electronic devices to be tested on four electronic device conveying media in the simultaneously measured number of 32.

FIG. 17 is a view of test positions in the first round of electronic devices to be tested arranged on electronic device conveying media when conducting a test on electronic devices to be tested on four electronic device conveying media in the simultaneously measured number of 32.

FIG. 18 is a view showing a detailed configuration of a test head portion and around it of the second embodiment of the present invention.

FIG. 19 is a view showing an arrangement of respective contact groups when conducting a test on electronic devices to be tested on two electronic device conveying media in the simultaneously measured number of 32 of the second embodiment of the present invention.

FIG. 20 is a view showing test positions in the first round arranged on electronic device conveying media when conducting a test on electronic devices to be tested on two electronic device conveying media in the simultaneously measured number of 32 of the second embodiment of the present invention.

FIG. 21 is a view showing arrangements of respective prober groups corresponding to a test of electronic devices arranged on a wafer in a third embodiment of the present invention.

FIG. 22 is a view showing test positions in a first prober group and a second prober group.

FIG. 23 is a view showing test positions in a third prober group and a fourth prober group.

FIG. 24 is a view showing a strip format on which electronic devices are arranged in four rows by eleven columns.

FIG. 25 is a view showing an arrangement of conventional one contact group composed of contact portions having the simultaneously measured number of 32 (4 rows by 8 columns).

FIG. 26 is a view showing an arrangement of conventional one contact group composed of contact portions having the simultaneously measured number of 64 (4 rows by 16 columns).

FIG. 27 is a view showing positions able to be measured at a time in the first test and the second test in the case of electronic device conveying media (3 rows by 16 columns).

### BEST MODE FOR CARRYING OUT THE INVENTION

Below, preferred embodiments of the present invention will be explained based on the drawings.

### Embodiment 1

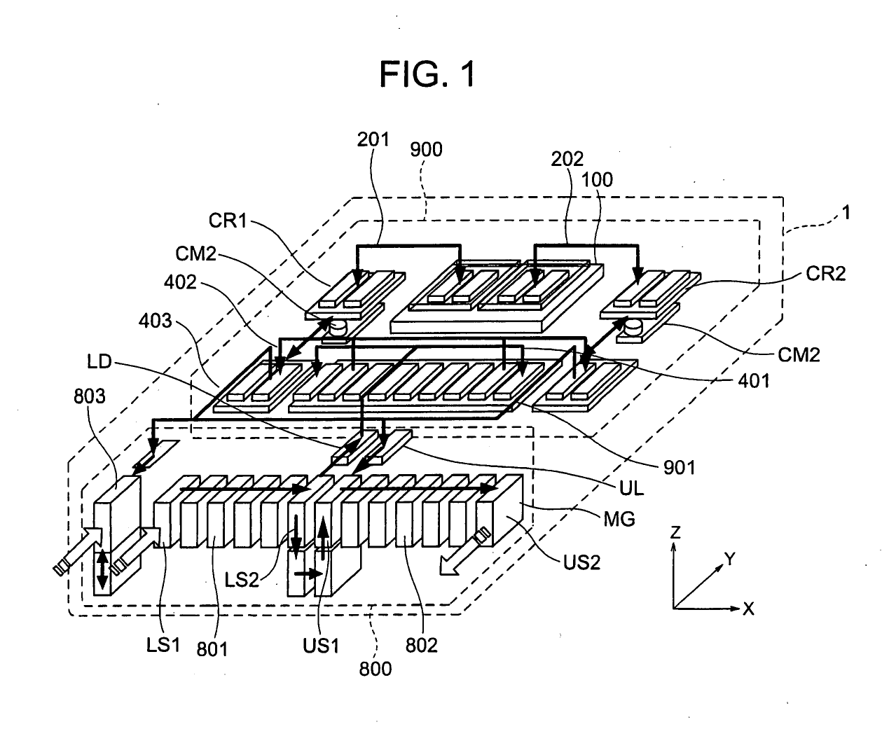

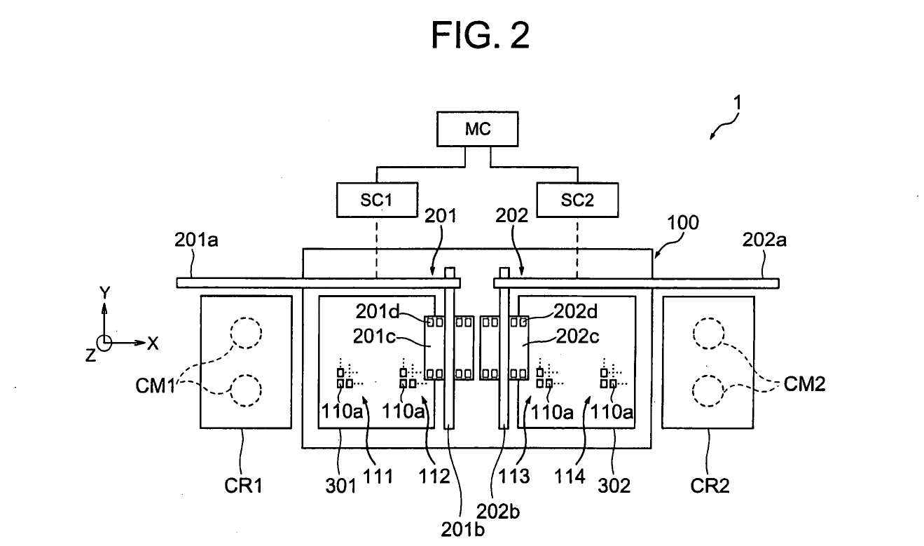

FIG. 1 is a schematic view of an electronic device testing apparatus in a first embodiment of the present invention, and FIG. 2 is a view showing a test head portion 100, a detailed configuration of around it and the control system of an electronic device testing apparatus of the present invention.

The electronic device testing apparatus 1 of the present embodiment is an apparatus for conducting a test (inspection) whether electronic devices 20 operate suitably in a state that the electronic devices to be tested 20 are applied with a thermal stress of a high temperature or low temperature, and classifying the electronic devices 20 in accordance with the test results; wherein an operation test in a state of applying such thermal stresses is conducted by conveying an electronic device conveying medium 10 loaded with the electronic devices to be tested 20 as test objects to the electronic device testing apparatus 1.

Therefore, the electronic device testing apparatus 1 of the present embodiment comprises, as shown in FIG. 1, an electronic devices storing portion 800 for storing pre-test electronic devices to be tested 20 and storing post-test electronic devices to be tested 20; a loader section LD for feeding electronic devices to be tested 20 fed from the electronic device storing section 800 to a chamber section 900; a chamber section 900 including a test head portion 100 for conducting a test; and an unloader section UL for taking out post-test electronic devices 20 tested in the chamber section 900.

### Electronic Device Storing Section 800

The electronic device storing section 800 is provided with a pre-test electronic device stocker 801 for storing pre-test electronic devices to be tested 20, a post-test electronic device stocker 802 for storing post-test electronic devices 20, and a retest electronic device stocker 803 for storing electronic devices 20 judged to be requiring a retest.

The pre-test electronic device stocker 801 comprises a supply position LS1 of magazines MG from the previous step; a not shown conveying means in the X-axis direction for storing a plurality of magazines MG and moving successively to a supply position LS2 of electronic device conveying media 10 to the loader section LD; a supply position LS2 of electronic device conveying media 10 to the loader section LD; and a not shown position control means in the Z-axis direction for assisting supply to the loader section LD.

In the pre-test electronic device stocker 801, a certain number of electronic device conveying media 10 loaded with pre-test electronic devices 20 are supplied to the supply position LS1 of the magazine MG from the previous step in a state of carried in the magazine MG.

The magazine MG carrying a certain number of electronic device conveying media 10 loaded with the supplied pre-test electronic devices 20 is successively moved close to the supply position LS2 of the electronic device conveying medium 10 to the loader section LD by the not shown conveying means in the X-axis direction, and stored with a plurality of the magazines MG supplied on the not shown conveying means in the X-axis direction (in FIG. 1, for example 6 magazines MG are stored).

In the magazine MG reached to the supply position LS2 of the electronic device conveying medium 10 to the loader section LD by being moved by the not shown conveying means in the X-axis direction, a first conveying means 401 of the loader section LD conveys from the top of the electronic device conveying media 10 in the magazine MG by one at a time to the loader section LD.

At this time, in the supply position LS2 of the electronic device conveying medium 10 to the loader section LD, for example, an electronic device conveying medium 10 loaded with pre-test electronic devices 20 is supplied from the top among the electronic device conveying media 10 loaded with pre-test electronic devices 20 carried in the magazine MG. It is configured that every time one electronic device conveying medium 10 loaded with pre-test electronic devices 20 is supplied, the magazine MG is elevated in the Z-axis direction by a certain pitch by a not shown Z-axis actuator and a position of an electronic device conveying medium 10 loaded with pre-test-electronic devices 20 on top among the electronic device conveying media 10 loaded with pre-test electronic devices 20 carried in the magazine MG can be always kept at the same height. It assists supply from the magazine MG of the electronic device conveying media 10 loaded with pre-test electronic devices 20 by a first conveying means 401 of the loader section LD.

Also, the same magazine MG is used in the pre-test electronic device stocker 801 and the post-test electronic device stocker 802. As shown in FIG. 1, an empty magazine MG after supplying all electronic device conveying media 10 carried in the magazine MG by the conveying means 401 of the loader section LD in the pre-test electronic device stocker 801 is moved from the supply position LS2 of the electronic device conveying medium 10 to loader section LD to a supply position US1 of the electronic device conveying medium 10 from the unloader section UL in the post-test electronic device stocker 802 and used as it is in the post-test electronic device stocker 802. Namely, the magazine MG is continuously used from the pre-test electronic device stocker 801 to the post-test electronic device stocker 802.

The post-test electronic device stocker 802 comprises the supply position US1 of the electronic device conveying medium 10 from the unloader section UL; a not shown conveying means in the X-axis direction for storing a plurality of magazines MG and successively moving to a discharge position US2 of magazines MG to the next step; the discharge position US2 of the magazine MG to the next step; and a not shown position control means in the Z-axis direction positioned at the magazines MG discharge position US2 to the next step for assisting carriage from the unloader section UL.

In the post-test electronic device stocker 802, an electronic device conveying medium 10 loaded with post-test electronic device 20 is loaded one at a time on an empty magazine MG moved from the pre-test electronic device stocker 801 by a third conveying means 403 of the unloader section UL at the supply position US1 of the electronic device conveying media 10 from the unloader section UL.

At this time, in the supply position US1 of the electronic device conveying medium 10 from the unloader section UL, for example, loading starts from the bottom of the magazine MG, so that an electronic device conveying medium 10 loaded with post-test electronic devices 20 to be loaded next positions on top of the electronic device conveying media 10 loaded with post-test electronic devices 20 already loaded in the magazine MG. It is configured that every time one electronic device conveying medium 10 loaded with post-test electronic devices 20 is loaded, a not shown Z-axis actuator lowers the magazine MG in the Z-axis direction at a certain pitch, so that a position the next electronic device conveying medium 10 loaded with post-test electronic devices 20 should be loaded can be always kept at the same height, and loading of electronic device conveying media 10 loaded with post-test electronic devices 20 to the magazine MG by the third conveying means 403 of the unloader section UL is assisted.

A certain number of electronic device conveying media 10 loaded with post-test electronic devices 20 are loaded in one magazine MG. Furthermore, a magazine MG loaded with the certain number of electronic device conveying media 10 loaded with post-test electronic devices 20 is successively moved close to the discharge position US2 of the magazine MG to the next step by being moved by the not shown conveying means in the X-axis direction, and a plurality of the supplied magazines MG are stored on the not shown conveying means in the X-axis direction (in FIG. 1, for example, 6 magazines MG are stored). A magazine MG reached at the magazine discharge position US2 is discharged in the next step.

Also, the above pre-test electronic device stocker 801 is provided with a retest electronic device stocker 803, and the retest electronic device stocker 803 is provided with an empty magazines MG. An electronic device conveying medium 10 loaded with an electronic device 20 judged to be requiring a retest in the test is loaded to the empty magazine MG from a later explained first electronic device conveying medium carrier CR1 or a second electronic device conveying medium carrier CR2 by the third conveying means 403.

At this time, in the retest electronic device stocker 803, for example, loading starts from the bottom of the magazine MG, so that an electronic device conveying medium 10 loaded with an electronic device 20 judged to be requiring a retest to be loaded next always positions on top of electronic device conveying media 10 loaded with an electronic device 20 judged to be requiring a retest already loaded in the magazine MG. It is configured that every time an electronic device conveying medium 10 loaded with an electronic device 20 judged to be requiring a retest is loaded, a not shown Z-axis actuator lowers the magazine MG to the Z-axis direction at a certain pitch, so that a position the next electronic device conveying medium 10 loaded with an electronic device 20 judged to be requiring a retest should position can be always kept at the same height. It assists loading of electronic device conveying media 10 loaded with an electronic device 20 judged to be requiring a retest to the magazine MG by the third conveying means 403 of the unloader section UL.

The magazine MG carrying the electronic device conveying medium 10 loaded with an electronic device 20 judged to be requiring a retest in the retest electronic device stocker 803 is again supplied to the magazine supply position LS1 from the previous step in the pre-test electronic device stocker 801.

Loader Section LD

The loader section LD comprises a first conveying means 401 for taking out an electronic device conveying medium 10 loaded with pre-test electronic devices 20 from the pre-test electronic device stocker 801 and supplying to the chamber section 900.

The first conveying means 401 is, for example, a means capable of moving grip heads for gripping one electronic device conveying medium 10 and moving the gripped electronic device conveying medium 10 in the X-Y-Z axes directions.

Among electronic device conveying media 10 loaded with pre-test electronic device 20 carried in a magazine MG reached at the supply position LS2 of electronic device conveying medium 10 to the loader section LD in the pre-test electronic device stocker 801, an electronic device conveying medium 10 loaded with pre-test electronic devices 20 positioned on top is gripped by the first conveying means 401 and moved to a buffer portion 901 in a constant chamber.

Chamber Section 900

The chamber section 900 comprises a constant chamber for giving a thermal stress of a high temperature or a low temperature to an electronic device conveying medium 10 loaded with electronic devices to be tested 20 for testing; a buffer portion 901 for securing time for applying the thermal stress to the electronic device conveying medium 10 loaded with electronic devices to be tested 20 supplied from the loader section LD; a second conveying means 402 for moving the electronic device conveying medium 10 loaded with electronic devices to be tested 20 in a state of being applied a thermal stress in the buffer portion 901 by the constant chamber to a first electronic device conveying medium carrier CR1 or a second electronic device conveying medium carrier CR2; a first electronic device conveying medium carrier CR1 and a second electronic device conveying medium carrier CR2 for aligning a position of one or more electronic device conveying medium 10 loaded with electronic devices to be tested 20 and moving the electronic device conveying medium 10 to the test head portion 100, and a test head portion for conducting a test.

The constant chamber is configured to cover all of the above buffer portion 901, the second conveying means 402, the first electronic device conveying medium carrier CR1 and second electronic device conveying medium carrier CR2, and the test head portion 100 for applying and maintaining a thermal stress of a high temperature or a low temperature to electronic devices to be tested 20 loaded on the electronic device conveying medium 10.

Also, when applying a thermal stress of a high temperature or a low temperature to electronic devices to be tested 20, a certain time is necessary, so that the buffer portion 901 is provided for securing the time when applying a thermal stress to inside the constant chamber. As shown in FIG. 1, the buffer portion 901 is configured that a certain number of electronic device conveying media 10 (nine electronic device conveying media 10 at a time in FIG. 1) can be arranged, so that the thermal stress can be applied to a plurality of electronic device conveying media 10 at a time.

The electronic device conveying medium 10 loaded with electronic devices to be tested 20 sufficiently applied with a thermal stress in the buffer portion 901 is moved to the first electronic device conveying medium carrier CR1 or the second electronic device conveying medium carrier CR2 by the second conveying means 402.

The second conveying means 402 is, for example, a means capable of moving grip heads for gripping one or more electronic device conveying medium 10 loaded with pre-test electronic devices 20 or one or more electronic device conveying medium 10 loaded with post-test electronic devices 20 and moving the gripped electronic device conveying medium 10 in the X-Y-Z axes directions.

Note that operation ranges of the first conveying means 401, the second conveying means 402 and the third conveying means 403 partially overlap to one another, but interference of operations of mutual conveying means can be prevented by configuring that heights of rails and movable arms in the X-axis and Y-axis directions differ from one another and, furthermore, by controlling.

The first electronic device conveying medium carrier CR1 is, for example, a conveying means capable of moving back and forth in the Y-axis direction from an operation range of the third conveying means 403 to above a first camera CM1 in an operation range of the first moving device 201 while keeping the posture of the electronic device conveying medium 10.

Also, an upper surface of the first electronic device conveying medium carrier CR1 has, for example, a configuration of a concave portion along an outline of a plurality of the electronic device conveying media 10 able to be gripped by the first moving device 201, and a circumference of the concave portion has a shape surrounded by inclined planes. Thus, when an electronic device conveying medium 10 loaded with electronic devices to be tested 20 gripped by grip heads of the second conveying means 402 is dropped into the concave portion, the dropping position of the electronic device conveying medium 10 is corrected on the inclined planes. Consequently, mutual positions of the plurality of electronic device conveying media 10 (two electronic device conveying media 10 in FIG. 1) are correctly aligned, and the electronic device conveying media 10 whose positions are corrected can be matched accurately in pitches of a plurality of grip heads 201d of the first moving device 201.

The first electronic device conveying medium carrier CR1 aligns positions of the plurality of electronic device conveying media 10 in order to supply the electronic device conveying media 10 loaded with pre-test electronic devices 20 conveyed as far as the buffer portion 901 by one at a time to the first moving device 201 by many at a time and, furthermore, moves to a position above the first camera CM1 in the operation range of the first moving device 201.

Furthermore, after the first electronic device conveying medium carrier CR1 moves to above the first camera CM1, an instruction of operation start is sent to the first moving device 201 when the first camera CM1 recognizes an existence of the electronic device conveying media 10.

The second electronic device conveying medium carrier CR2 is, for example, a conveying means capable of moving back and forth in the Y-axis direction from an operation range of the third conveying means 403 to above a second camera CM2 in an operation range of the second moving device 202 while keeping the posture of the electronic device conveying medium 10.

Also, an upper surface of the second electronic device conveying medium carrier CR2 has, for example, a configuration of a concave portion along an outline of a plurality of the electronic device conveying media 10 able to be gripped by the second moving device 202, and a circumference of the concave portion has a shape surrounded by inclined planes. Thus, when an electronic device conveying medium 10 loaded with electronic devices to be tested 20 gripped by grip heads of the second conveying means 402 is dropped into the concave portion, the dropping position of the electronic device conveying medium 10 is corrected on the inclined planes. Consequently, mutual positions of the plurality of electronic device conveying media 10 (two electronic device conveying media 10 in FIG. 1) are correctly aligned, and the electronic device conveying media 10 whose positions are corrected can be matched accurately in pitches of a plurality of grip heads 202d of the second moving device 202.

The second electronic device conveying medium carrier CR2 aligns positions of the plurality of electronic device conveying media 10 in order to supply the electronic device conveying media 10 loaded with pre-test electronic devices 20 conveyed as far as the buffer portion 901 by one at a time to the second moving device 202 by many at a time and, furthermore, moves to a position above the second camera CM2 in the operation range of the second moving device 202.

Furthermore, after the second electronic device conveying medium carrier CR2 moves to above the second camera CM2, an instruction of operation start is sent to the second moving device 202 when the second camera CM2 recognizes an existence of the electronic device conveying media 10.

The electronic device conveying medium 10 loaded with electronic devices 20 tested in by the test head portion 100 is reloaded to the first electronic device conveying medium carrier CR1 above the first camera CM1 by the first moving device 201 and moved to an operation range of the third conveying means 403.

In the same way, the electronic device conveying medium 10 loaded with electronic devices 20 tested by the test head portion 100 is reloaded to the second electronic device conveying medium carrier CR2 above the second camera CM2 by the second moving device 202 and moved to an operation range of the third conveying means 403.

When the electronic devices to be tested 20 loaded on the electronic device conveying medium 10 are made to be a high temperature, the electronic devices to be tested 20 are cooled to the room temperature by blowing air in a state of being carried on the first electronic device conveying medium carrier CR1 or second electronic device conveying medium carrier CR2 while loaded on the electronic device conveying medium 10; while when made to be a low temperature, the electronic devices to be tested 20 are heated by blowing hot air or a heater to return to a temperature of a degree of not causing dew condensation while loaded on the electronic device conveying medium 10. The electronic device conveying medium 10 loaded with the temperature adjusted electronic devices to be tested 20 is conveyed out to the unloader section UL.

Note that although the respective moving devices 201 and 202 are capable of freely determine the number of electronic device conveying media 10 able to be gripped independently from other moving devices and the gripping number within the number, the number of electronic device conveying media 10 able to be gripped by the first moving device 201 and the number of electronic device conveying media 10 able to be carried by the first electronic device conveying medium carrier CR1 are not always matched, or the number of electronic device conveying media 10 able to be gripped by the second moving device 202 and the number of electronic device conveying media 10 able to be carried by the second electronic device conveying medium carrier CR2 are not always matched. For example, there is considered a method of making the index time short by making the number of electronic device conveying media 10 able to be carried on the first electronic device conveying medium carrier CR1 to be two times as much as the number of electronic device conveying media 10 able to be gripped by the first moving device 201. Namely, there is considered a method of making the index time short as a result that during the first moving device 201 conducts a test, the first electronic device conveying medium carrier CR1 returns to the operation range of the third conveying means 403, the next electronic device conveying medium 10 loaded with pre-test electronic devices 20 is received from the buffer portion 901 via the third conveying means 403 and moved to above the first camera CM1 in the operation range of the first moving device 201, the electronic device conveying medium 10 loaded with post-test electronic devices 20 is received, and the next electronic device conveying medium 10 loaded with pre-test electronic devices 20 is immediately supplied.

Note that the test head portion 100 will be explained in detail later on.

Unloader Section UL

The unloader section UL comprises a third conveying means 403 for conveying an electronic device conveying medium 10 loaded with post-test electronic devices 20 from the first electronic device conveying medium carrier CR1 or the second electronic device conveying medium carrier CR2 to the post-test electronic device stocker 802 or the retest electronic device stocker 803 in an electronic device storing portion 800.

The third conveying means 403 is, for example, a means capable of moving grip heads for gripping one electronic device conveying medium 10 and moving the gripped electronic device conveying medium 10 in the X-Y-Z axes directions.

The electronic device conveying medium 10 loaded with post-test electronic devices 20 is moved from the first electronic device conveying medium carrier CR1 or second electronic device conveying medium carrier CR2 on the operation range of the third conveying means 403 to the supply position US1 of the electronic device conveying medium 10 from the unloader section UL in the post-test electronic device stocker 802 by the third conveying means 403, and the electronic device conveying medium 10 is loaded in a magazine MG at the supply position US1 of the electronic device conveying medium 10 from the unloader section UL.

Also, when an electronic device on the electronic device conveying medium 10 is judged to be requiring a retest by the test, the electronic device conveying medium 10 is loaded in the magazine MG in the retest electronic device stocker 803 of the electronic device storing portion 800 by the third conveying means from the first electronic device conveying medium carrier CR1 or the second electronic device conveying medium carrier CR2 on the operation range of the third conveying means 403.

Test Head Portion 100

The electronic device conveying medium 10 is supplied to the test head portion 100 by the first electronic device conveying medium carrier CR1 or second electronic device conveying medium carrier CR2, and a test is conducted while the electronic devices to be tested 20 are loaded on the electronic device conveying medium 10.

The test head portion 100 comprises four contact groups, that is a first contact group 111, second contact group 112, third contact group 113 and a fourth contact group 114, for conducting a test on pre-test electronic devices 20 arranged on an electronic device conveying medium 10 supplied by the first electronic device conveying medium carrier CR1 or second electronic device conveying medium carrier CR2; a first moving device 201 for controlling a position and posture of an electronic device conveying medium 10 loaded with electronic devices to be tested 20 in a first range 301 covering above the first contact group 111 and above the second contact group 112 and a range including a first electronic device conveying medium carrier CR1 above the first camera CM1; and a second moving device 202 for controlling a position and posture of electronic device conveying medium 10 loaded with electronic devices to be tested 20 in a second range 302 covering above the third contact group 113 and the fourth contact group 114 and a range including the second electronic device conveying medium carrier CR2 above the second camera CM2.

The first moving device 201 is a means for controlling positions of a plurality of electronic device conveying media 10 (two electronic device conveying media in FIG. 1) in the X-Y-Z axes directions and controlling a posture in the θ-angle direction by using the Z-axis as a center axis. For example, it is configured to be able to move in the first range 301 above the first contact group 111 and the second contact group 112 and a range including above the first electronic device conveying medium carrier CR1 above the first camera CM1 by a rail 201a provided along the X-axis direction, a movable arm 201b moving on the rail 201a in the X-axis direction, and a movable head 201c supported by the movable arm 201b and capable of moving along the movable arm 201b in the Y-axis direction.

The movable head 201c is also movable in the Z-axis direction (that is, in the vertical direction) by a not shown Z-axis actuator and, furthermore, controllable in the θ-angle direction by using the Z-axis as a center axis by a not shown posture control function. It is possible to grip, convey and release a plurality of electronic device conveying media 10 (two in the case in FIG. 1) at a time by a plurality of grip heads 201d (for example, 8 suction heads) provided to the movable head 201c.

One electronic device to be tested 20 on the electronic device conveying medium 10 corresponds to one contact 110a, and respective electronic devices to be tested 20 loaded on an electronic device conveying medium 10 gripped by grip heads 201d are applied a suitable pressure by an operation of the movable head 201c in the downward Z-axis direction and made to contact not shown contact pins on the contact 110a, so that a test is conducted. The test result is, for example, stored at an address determined by an identification number attached to an electronic device conveying medium 10 and an electronic device number assigned inside the electronic device conveying medium 10.

The first contact group 111 is composed of a set of contact portions 110a for conducting a test on electronic devices 20, and the second contact group 112, third contact group 0.113 and fourth contact group 114 are composed of sets of contact portions 110a in the same way.

As far as the number of contact portions 110a in total in an electronic device testing apparatus 1 matches with the simultaneously measured number limited in the electronic device testing apparatus 1 (Normally, the number of test positions able to be measured at a time, that is the simultaneously measured number, is limited to 2ⁿ, such as 32 or 64, per one electronic device testing apparatus 1. Note that “n” is a natural number), it is possible to determine optimal number and arrangement of contact portions 110a in the respective contact groups 111, 112, 113 and 114 in accordance with the number and arrangement of electronic devices to be tested 20 on the electronic device conveying medium 10 and a production plan, etc. Namely, as far as the total number of contact portions 110a of the first contact group 111, second contact group 112, third contact group 113 and fourth contact group 114 matches with the simultaneously measured number of 32 or 64 limited in the electronic device testing apparatus 1, the number of contact portions 110a in the respective contact groups 110 can be freely set.

Also, pitches between the respective contact portions 110a in the contact groups 111, 112, 113 and 114 have relationship of being identical with multiples of pitches (including 1) between respective electronic devices 20 arranged on electronic device conveying medium 10 corresponding to the respective contact groups 111, 112, 113 and 114.

Furthermore, as shown in FIG. 4, FIG. 7, FIG. 10, FIG. 13 and FIG. 16, the number of contact groups 110 in the electronic device testing apparatus 1 may be provided to be an optimal number in accordance with the number and arrangement of electronic devices to be tested 20 on an electronic device conveying medium 10 and a production plan, etc. By mutually independently providing by making the first moving device 201 correspond to the first contact group 111 and the second contact group 112, and the second moving device 202 to the third contact group 113 and fourth contact group 114; two contact groups, that is the first contact group 111 and the second contact group 112, and two contact groups, that is the third contact group 113 and the fourth contact group 114, are capable of operating independently from one another.

Also, by holding a plurality of electronic device conveying media 10 (two in the case in FIG. 1) by one moving device, facility costs and the occupying area can be suppressed and the simultaneously measured number can be secured while making the number of moving devices on the test head portion 100 as less as possible.

As to the basic configuration and operation of the second moving device 202, it is a means for controlling positions of a plurality of electronic device conveying media 10 in the X-Y-Z axes directions and controlling a posture in the θ-angle direction using the Z-axis as a center axis in the same way as the above first moving device 201 and, for example, configured to be able to move in a second range 302 above the third contact group 113 and the fourth contact group 114 and a range including above the second electronic device conveying medium carrier CR2 above the second camera CM2 due to a rail 202a provided along the X-axis direction, a movable arm 202b moving on the rail 202a in the X-axis direction, and a movable head 202c supported by the movable arm 202b and movable along the movable arm 202b in the Y-axis direction.

The movable head 202c is movable in the Z-axis direction (that is, in the vertical direction) by a not shown Z-axis actuator and, furthermore, control of the θ-angle by using the Z-axis as a center axis is also possible by a not shown posture control function. Also, a plurality of electronic device conveying media 10 (two in the case in FIG. 1) can be gripped, conveyed and released at a time by a plurality of grip heads 202d (for example, 8 suction heads) provided to the movable head 202c.

On an upper portion of FIG. 2 shows an outline of a control system of the electronic device testing apparatus 1, and the control system comprises a main controller MC, a first sub controller SC1, and a second sub controller SC2.

The main controller MC collectively manages the first sub controller SC1 and the second sub controller SC2 to perform control in the Z-axis direction for tests on the first moving device 201, control in the Z-axis direction for tests on the second moving device 202, and control of outputting a start request signal to the first contact group 111, the second contact group 112, the third contact group 113 and the fourth contact group 114. As a result, test timings in the first contact group 111, the second contact group 112, the third contact group 113 and the fourth contact group 114 can be synchronized, and the simultaneously measured number can be secured.

Furthermore, the first sub controller SC1 performs control relating to moving in the X-Y-Z directions and a posture in the θ-angle direction of the first moving device 201 excepting for those performed by the main controller MC, the second sub controller SC2 performs control of moving in the X-Y-Z directions and a posture in the θ-angle direction of the second moving device 202 excepting for those performed by the main controller MC. Consequently, the three moving devices can be controlled independently from one another.

In the above example, the explanation was made in premise that there are four contact groups 110 and two moving devices, and the two moving devices 201 and 202 can respectively grip two electronic device conveying media 10. But it is not limited to these, the number of contact groups 110 (for example, one to three contact groups 110 or five or more contact groups 110) and the number and arrangement of contact portions 110a in each contact group 110 can be optimally determined in accordance with the number and arrangement of electronic devices to be tested 20 on the electronic device conveying medium 10 and a production plan, etc. Also, the number of the mutually independent moving devices (for example, one moving device or three or more moving devices), a contact group 110 corresponding to each moving device, the number of electronic device conveying media 10 able to be gripped by each moving device (for example, a moving device capable of gripping one or three or more electronic device conveying media 10), the number of electronic device conveying media 10 gripped freely and independently from other moving devices within the number able to be gripped by the respective moving devices can be optimally set for each moving device.

Note that when the number of contact groups 110 increases, the occupying area of the facility increases, while when the number of the contact groups 110 is decreased, the simultaneously measured number becomes hard to be secured.

Also, when the number of moving devices increases, the facility const and occupying area increase, and when the number of electronic device conveying media 10 able to be gripped by one moving device increases, it is hard to obtain positional accuracy. Accordingly, it is necessary to compare and consider the occupying area, facility costs and alignment accuracy, etc. to determine the optimal number of contact groups 110, the number and arrangement of contact portions 110a in the contact group 110, the number of mutually independent moving devices, a contact group 110 corresponding to each moving device, the number of electronic device conveying media able to be gripped by one moving device, and the number of electronic device conveying media 10 freely gripped by each moving device within the number able to be gripped independently from other moving devices in accordance with the number and arrangement of electronic devices to be tested 20 on an electronic device conveying medium 10 and a production plan, etc.

Next, an operation will be explained.

The test head portion 100 of the electronic device testing apparatus 1 comprises the first moving device 201 capable of moving in a first range 301 covering above the first contact group 111 and the second contact group 112 and a range including above the first electronic device conveying medium carrier CR1 above the first camera CM1, and the second moving device 202 movable in a second range 302 covering above the third contact groups 113 and the fourth contact group 114 and a range including above the second electronic device conveying medium carrier CR2 above the second camera CM2. The number of electronic device conveying media 10 able to be gripped is 2 in each of the moving devices 201 and 202.

Also, the electronic device conveying medium 10 loaded with pre-test electronic devices 20 aligned and supplied by the first electronic device conveying medium carrier CR1 is tested at the first contact group 111 and the second contact group 112 by the first moving device 201.

Also, the electronic device conveying medium 10 loaded with pre-test electronic devices 20 aligned and supplied by the second electronic device conveying medium carrier CR2 is tested at the third contact group 113 and the fourth contact group 114 by the second moving device 202.

Below, a testing method capable of flexibly dealing by freely combining the gripping number of electronic device conveying media according to circumstances within the number able to be gripped by the respective moving devices in the case of using the electronic device testing apparatus 1 particularly when the simultaneously measured number of the test head portion is 32, namely, each of specific testing methods in the case where the electronic device conveying medium 10 is one, the case of two, another example in the case of two, the case of three and the case of four will be explained.

Note that below, an electronic device conveying medium 11 indicates an electronic device conveying medium arranged with 32 electronic devices to be tested 20 in four rows by eight columns to be subjected to a test at the first contact group 111, an electronic device conveying medium 12 indicates an electronic device conveying medium arranged with 32 electronic devices to be tested 20 in four rows by eight columns to be subjected to a test at the second contact group 112, an electronic device conveying medium 13 indicates an electronic device conveying medium arranged with 32 electronic devices to be tested 20 in four rows by eight columns to be subjected to a test at the third contact group 113, and an electronic device conveying medium 14 indicates an electronic device conveying medium arranged with electronic devices to be tested 20 in four rows by eight columns to be subjected to a test at the fourth contact group 114.

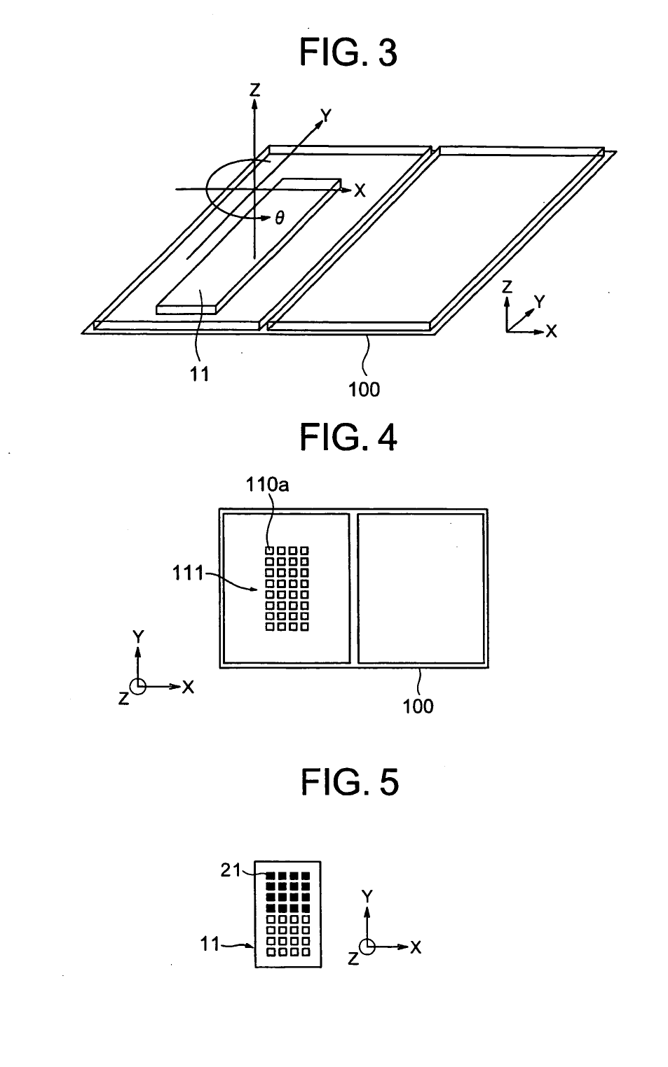

FIG. 3 shows corresponding relationship of an electronic device conveying medium 11 and the respective contact groups 111, 112, 113 and 114 in the case of one electronic device conveying medium 11 loaded with electronic device to be tested 20. In this case, one electronic device conveying medium 11 is gripped by the first moving device 201 having grip heads 201d capable of gripping two electronic device conveying media 11 and 12. Accordingly, the first electronic device conveying medium carrier CR1 does not supply the electronic device conveying medium 12 to the first moving device 201, and the second electronic device conveying medium carrier CR2 does not supply the electronic device conveying media 13 and 14 to the second moving device 202.

FIG. 4 shows an arrangement of the contact group 110 in the case of the simultaneously measured number of 32 corresponding to FIG. 3, wherein the number of contact portions 110a in the first contact group 111 is set to be 32 (four rows by eight columns), and the numbers of the contact portions 110a in the second contact group 112, the third contact group 113 and the fourth contact group 114 are all set to be zero for the four contact groups 111, 112, 113 and 114.

FIG. 5 shows the test positions 21 in the first round (The test positions 21 in the first round indicates all black squares in the figure. It is the same in FIG. 8, FIG. 11, FIG. 14, FIG. 17 and FIG. 20) of an arrangement of electronic devices to be tested 20 on an electronic device conveying medium 11 corresponding to FIG. 4, wherein the first electronic device conveying medium 11 loaded with electronic devices 20 to be tested at the first contact group 111. Note that since the number of contact portions 110a is set to be zero in all of the second contact group 112, third contact group 113 and fourth contact group 114, the electronic device conveying media 12, 13 and 14 to be objects thereof are not shown in FIG. 5.

The first electronic device conveying medium 11 aligned and supplied by the first electronic device conveying medium carrier CR1 is moved to a range above the first contact group 111 by the first moving device 201.

Next, the first moving device 201 moves electronic devices to be tested 20 on the first electronic device conveying medium 11 in FIG. 5 in a range from first row on the first column to the eighth row on the fourth column of the arrangement to above the first contact group 111.

Next, the first moving device 201 conducts a test in the first round on 32 electronic devices 20 in a range from the first row on the first column to the eighth row on the fourth column in an arrangement on the electronic device conveying medium 11, and the test is conducted for one time in total on one electronic device conveying medium 11.

After completing the test for one time in total, the post-tested first electronic device conveying medium 11 which comes first is discharged to the post-test electronic device stocker 802 or the retest electronic device stocker 803 by the first electronic device conveying medium carrier CR1 via the third conveying means 403 of the unloader section UL, and the next electronic device conveying medium 11 is supplied to the first moving device 201 by the first electronic device conveying medium carrier CR1.

As explained above, by securing the simultaneously measured number of 32 in the first contact group 111, and setting the number of contact portions 110a to zero in all of the second contact group 112, the third contact group 113 and the fourth contact group 114, the simultaneously measured number of 32 limited in the electronic device testing apparatus 1 can be always secured and a high testing efficiency can be realized.

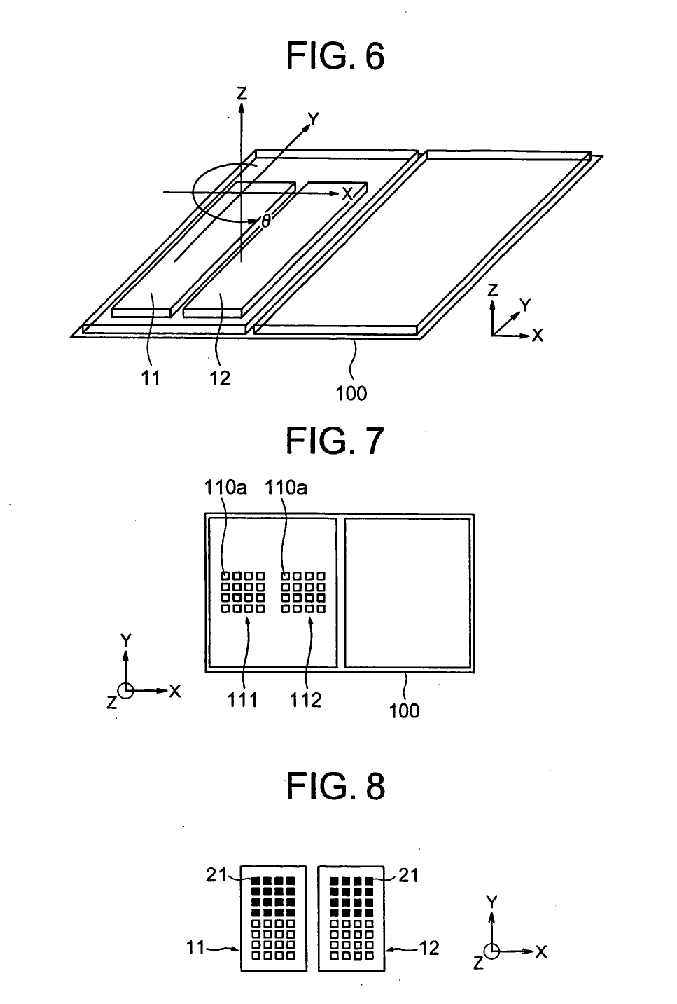

FIG. 6 shows corresponding relationship of an electronic device conveying media 11 and 12 and the respective contact groups 111, 112, 113 and 114 in the case of two electronic device conveying media 11 and 12 loaded with electronic device to be tested 20. In this case, two electronic device conveying media 11 and 12 are gripped by the first moving device 201 having grip heads 201d capable of gripping two electronic device conveying media 11 and 12. Accordingly, the second electronic device conveying medium carrier CR2 does not supply the electronic device conveying media 13 and 14 to the second moving device 202.

FIG. 7 shows an arrangement of the contact group 110 in the case of the simultaneously measured number of 32 corresponding to FIG. 6, wherein the number of contact portions 110a in the first contact group 111 is set to be 16 (four rows by four columns), the numbers of the contact portions 110a in the second contact group 112 is also set to be 16 (four rows by four columns), and the number of contact portions 110a of the third contact group 113 and the fourth contact group 114 are set to be zero for the four contact groups 111, 112, 113 and 114.

FIG. 8 shows the test positions 21 in the first round of an arrangement of electronic devices to be tested 20 on an electronic device conveying media 11 and 12 corresponding to FIG. 7, wherein the first electronic device conveying medium 11 loaded with electronic devices 20 to be tested at the first contact group 111, and the second electronic device conveying medium 12 loaded with electronic devices 20 to be tested at the second contact group 112 are shown. Note that since the number of contact portions 110a is set to zero in both of the third contact group 113 and fourth contact group 114, the electronic device conveying media 13 and 14 to be objects thereof are not shown in FIG. 8.

Two electronic device conveying media, that is the first electronic device conveying medium 11 and the second electronic device conveying medium 12, aligned and supplied by the first electronic device conveying medium carrier CR1 are gripped by the grip heads 201d of the first moving device 201 at a time and moved to the first range 301 above the first contact group 111 and the second contact group 112 by the first moving device 201.

Next, the first moving device 201 moves electronic devices to be tested 20 on the first electronic device conveying medium 11 in FIG. 8 in a range from first row on the first column to the fourth row on the fourth column of the arrangement to above the first contact group 111, and electronic devices to be tested 20 on the second electronic device conveying medium 12 in a range from first row on the first column to the fourth row on the fourth column of the arrangement are moved to above the second contact group 112 together at a time.

Next, the first moving device 201 conducts a test in the first round on 16 electronic devices 20 in a range from the first row on the first column to the fourth row on the fourth column in an arrangement of the first electronic device conveying medium 11, and 16 electronic devices 20 in a range from the first-row on the first column to the fourth row on the fourth column in an arrangement of the second electronic device conveying medium 12, and the test in the first round is conducted together at a time.

After the test finishes, the movable head 201c having grip heads 201d holding the first electronic device conveying medium 11 and the second electronic device conveying medium 12 is elevated, then, moved to the Y-axis direction by an amount of four rows by the first moving device 201.

Next, the first moving device 201 conducts a test in the second round on 16 electronic devices 20 in a range from the fifth row on the first column to the eighth row on the fourth column of the arrangement on the first electronic device conveying medium 11, and 16 electronic devices 20 in a range from the fifth row on the first column to the eighth row on the fourth column of the arrangement on the second electronic device conveying medium 12 together at a time, and tests are conducted for two times in total.

After completing the test for two times in total, the post-tested first electronic device conveying medium 11 which comes first and the post-tested electronic device conveying medium 12 which comes first are discharged to the post-test electronic device stocker 802 or the retest electronic device stocker 803 by the first electronic device conveying medium carrier CR1 via the third conveying means 403 of the unloader section UL, and the next electronic device conveying media 11 and 12 are supplied to the first moving device 201 by the first electronic device conveying medium carrier CR1.

Accordingly, tests are conducted for two times in total on one of first electronic device conveying media 11 and one of second electronic device conveying media 12, and tests on one of second electronic device conveying media 12 can be finished before the tests on one of first electronic device conveying media 11 finishes.

As explained above, by securing 16 test positions on the first contact group 111 and 16 test positions also on the second contact group 112, the simultaneously measured number of 32 limited in the electronic device testing apparatus 1 can be always secured and a high testing efficiency can be realized.

Note that, as shown in FIG. 7, when applying an arrangement of contact portion 110a as in the first contact group 111 and the second contact group 112 to an electronic device conveying medium having a point symmetry arrangement about the Z-axis as in the electronic device conveying media 11 and 12, a moving method below being different from that explained above is considered.

Two electronic device conveying media, that is the first electronic device conveying medium 11 and the second electronic device conveying medium 12, aligned and supplied by the first electronic device conveying medium carrier CR1 are gripped by grip heads 201d of the first moving device 201 at a time and moved to the first range 301 above the first contact group 111 and the second contact group 112 by the first moving device 201.

Next, the first moving device 201 moves electronic devices to be tested 20 on the first electronic device conveying medium 11 in FIG. 8 in a range from first row on the first column to the fourth row on the fourth column of the arrangement to above the first contact group 111, and electronic devices to be tested 20 on the second electronic device conveying medium 12 in a range from first row on the first column to the fourth row on the fourth column of the arrangement are moved to above the second contact group 112 together at a time.

Next, the first moving device 201 conducts a test in the first round on 16 electronic devices 20 in a range from the first row on the first column to the fourth row on the fourth column in an arrangement on the first electronic device conveying medium 11, and 16 electronic devices 20 in a range from the first row on the first column to the fourth row on the fourth column in an arrangement on the second electronic device conveying medium 12, and the test in the first round is conducted together at a time.

After completing the test, the movable head 201c having grip heads 201d holding the first electronic device conveying medium 11 and the second electronic device conveying medium 12 is elevated, then, rotated to the θ-angle direction by 180 degree about the Z-axis by the first moving device 201.

Next, a method of conducting a test in the second round by the first moving device 201 on 16 electronic devices 20 in a range from the fifth row on the first column to the eighth row on the fourth column of the arrangement on the first electronic device conveying medium 11 and 16 electronic devices 20 in a range from the fifth row on the first column to the eighth row on the fourth column of the arrangement on the second electronic device conveying medium 12 together at a time.

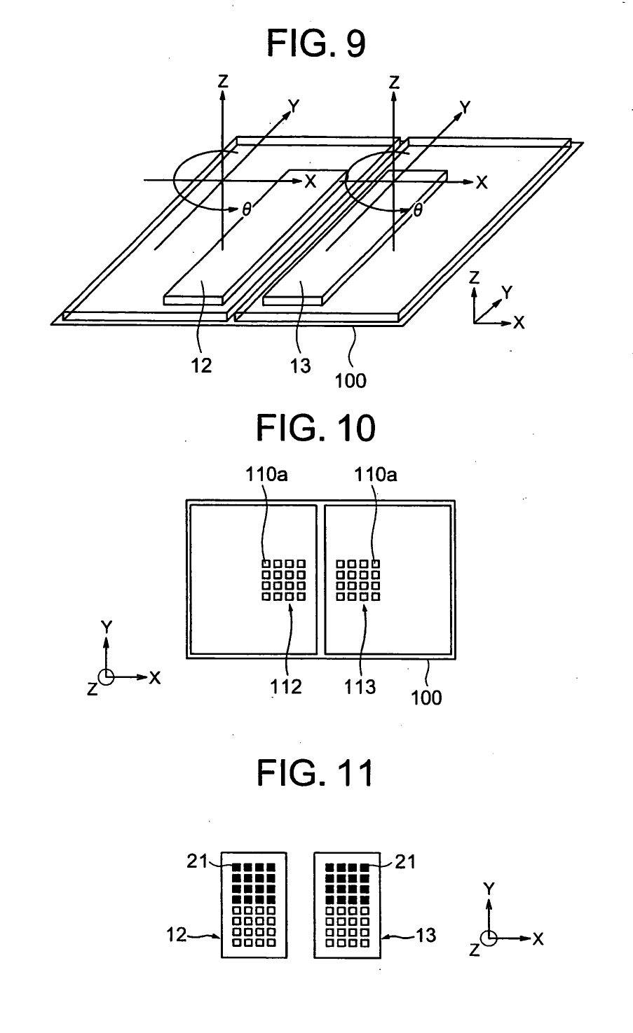

FIG. 9 shows corresponding relationship of electronic device conveying media 12 and 13 and the respective contact groups 111, 112, 113 and 114 in another example in the case of two electronic device conveying media 12 and 13 loaded with electronic device to be tested 20. In this case, one electronic device conveying medium 12 is gripped by the first moving device 201 having grip heads 201d capable of gripping two electronic device conveying media 11 and 12, and one electronic device conveying medium 13 is gripped by the second moving device 202 having grip heads 202d capable of gripping two electronic device conveying media 13 and 14 at a time. Accordingly, the first electronic device conveying medium carrier CR1 does not supply the electronic device conveying medium 11 to the first moving device 201 and the second electronic device conveying medium carrier CR2 does not supply the electronic device conveying medium 14 to the second moving device 202.

FIG. 10 shows an arrangement of the contact group 110 in the case of the simultaneously measured number of 32 corresponding to FIG. 9, wherein the number of contact portions 110a in the second contact group 112 is set to be 16 (four rows by four columns), the numbers of the contact portions 110a in the third contact group 113 is also set to be 16 (four rows by four columns), the number of contact portions 110a in the first contact group 111 and the fourth contact group 114 are set to be zero for the four contact groups 111, 112, 113 and 114.

FIG. 11 shows the test positions 21 in the first round of an arrangement of electronic devices to be tested 20 on the electronic device conveying media 12 and 13 corresponding to FIG. 10, wherein the second electronic device conveying medium 12 loaded with electronic devices 20 to be tested at the second contact group 112, and the third electronic device conveying medium 13 loaded with electronic devices 20 to be tested at the third contact group 113 are shown. Note that since the number of contact portions 110a is set to be zero in the first contact group 111 and fourth contact group 114, the electronic device conveying media 11 and 14 to be objects thereof are not shown in FIG. 11.

The electronic device conveying medium 12 aligned and supplied by the first electronic device conveying medium carrier CR1 is gripped by grip heads 201d of the first moving device 201 and moved to the first range 301 on the first contact group 111 and the second contact group 112 by the first moving device 201.

Next, the first moving device 201 moves the electronic devices to be tested 20 on the second electronic device conveying medium 12 in FIG. 11 in a range from the first row on the first column to the fourth row on the fourth column to above the second contact group 112.

Next, 16 electronic devices 20 in a range from the first row on the first column to the fourth row on the fourth column of an arrangement on the second electronic device conveying medium 12 are tested in the first round at the second contact group 112 by the first moving device 201.

When the test is finished, the movable head 201c having grip heads 201d holding the second electronic device conveying medium 12 is elevated by the first moving device 201, then, moved to the Y-axis direction by an amount of four rows.

Next, 16 electronic devices 20 in a range from the fifth row on the first column to the eighth row on the fourth column of an arrangement on the second electronic device conveying medium 12 are tested in the second round at the second contact group 112 by the first moving device 201, and tests are conducted for two times in total on one of second electronic device conveying media 12.

When the tests for two times in total are finished, the post-tested second electronic device conveying medium 12 which comes first is discharged to the post-test electronic device stocker 802 or the retest electronic device stocker 803 by the first electronic device conveying medium carrier CR1 via the third conveying means 403 of the unloader section UL, and the next electronic device conveying medium 12 is supplied to the first moving device 201 by the first electronic device conveying medium carrier CR1.

The third electronic device conveying medium 13 aligned and supplied by the second electronic device conveying medium carrier CR2 is gripped by grip heads 202d of the second moving device 202 and moved to the second range 302 above the third contact group 113 and the fourth contact group 114 by the second moving device 202, and electronic devices to be tested 20 in a range from the first row on the first column to the fourth row on the fourth column of the arrangement on the third electronic device conveying medium 13 are moved to above the third contact group 113.

Next, 16 electronic devices 20 in a range from the first row on the first column to the fourth row on the fourth column of the arrangement on the third electronic device conveying medium 13 are tested in the first round at the third contact group 113 by the second moving device 202.

When the test is finished, the movable head 202c having grip heads 202d holding the third electronic device conveying medium 13 in the second moving device 202 is elevated, then, moved to the Y-axis direction by an amount of four rows.

Next, 16 electronic devices 20 in a range from the fifth row on the first column to the eighth row on the fourth column of an arrangement on the third electronic device conveying medium 13 are tested in the second round at the third contact group 113 by the second moving device 202, and test is conducted for two times in total on one of third electronic device conveying media 13.

When the tests for two times in total are finished, the post-tested third electronic device conveying medium 13 which comes first is discharged to the post-test electronic device stocker 802 or the retest electronic device stocker 803 by the second electronic device conveying medium carrier CR2 via the third conveying means 403 of the unloader section UL, and the next electronic device conveying medium 13 is supplied to the second moving device 202 by the second electronic device conveying medium carrier CR2.

Accordingly; the test is conducted for two times in total on one of second electronic device conveying media 12 and one of third electronic device conveying media 13, and tests on one of third electronic device conveying media 13 can be finished before tests on one of second electronic device conveying media 12 finishes.

Note that test timing of the first moving device 201 and test timing of the second moving device 202 are synchronized by the main controller MC in the first moving device 201 and the second moving device 202, and tests are conducted at the same timing.

By controlling the two moving devices 201 and 202 independently by the respective sub controllers SC1 and SC2, securing 16 test positions in the second contact group 112 and 16 test positions also in the third contact group 113, the simultaneously measured number of 32 limited in the electronic device testing apparatus 1 can be always secured and a high testing efficiency can be realized.

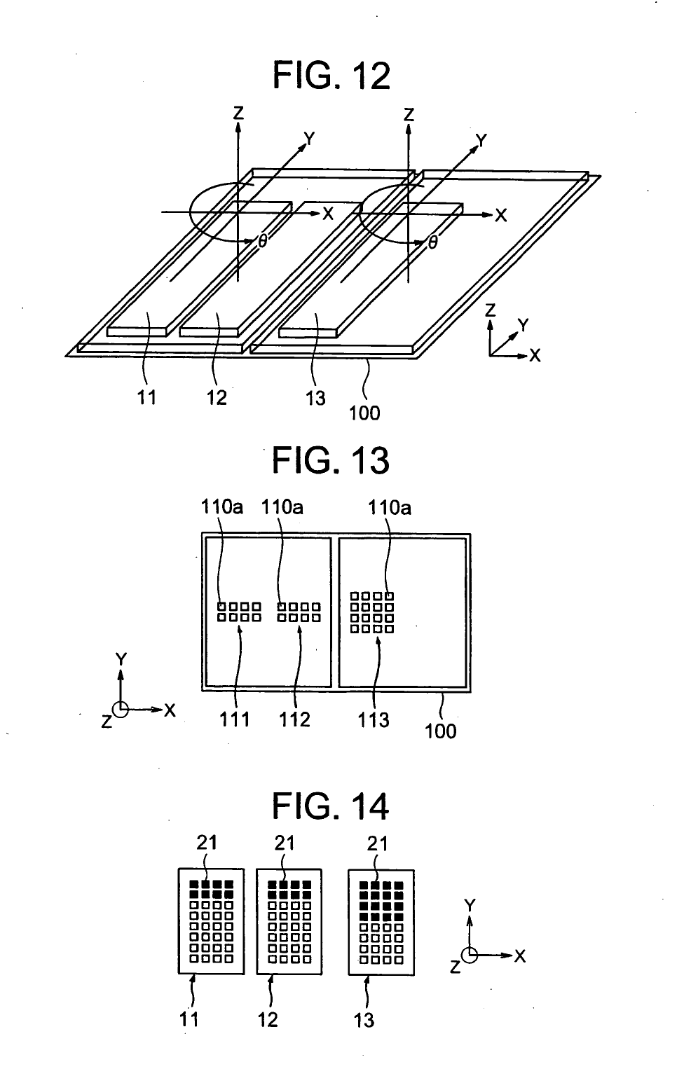

FIG. 12 shows corresponding relationship of electronic device conveying media 11, 12 and 13 and the respective contact groups 111, 112, 113 and 114 in an example in the case of three electronic device conveying media 11, 12 and 13 loaded with electronic device to be tested 20.

In this case, two electronic device conveying media 11 and 12 are gripped by the moving device 201 having grip heads 201d capable of gripping two electronic device conveying media 11 and 12 at a time, and one electronic device conveying medium 13 is gripped by the moving device 202 having grip heads 202d capable of gripping two electronic device conveying media 13 and 14 at a time. Accordingly, the second electronic device conveying medium carrier CR2 does not supply the electronic device conveying medium 14 to the second moving device 202.

FIG. 13 shows an arrangement of the contact group 110 in the case of the simultaneously measured number of 32 corresponding to FIG. 12, wherein the number of contact portions 110a in the first contact group 111 is set to be 8 (two rows by four columns), the number of contact portions 110a in the second contact group 112 is also set to be 8 (two rows by four columns), the numbers of the contact portions 110a in the third contact group 113 is set to be 16 (four rows by four columns), and the number of contact portions 110a in the fourth contact group 114 is set to be zero for the four contact groups 111, 112, 113 and 114.

FIG. 14 shows the test positions 21 in the first round of an arrangement of electronic devices to be tested 20 on the electronic device conveying media 11, 12 and 13 corresponding to FIG. 13, wherein the first electronic device conveying medium 11 loaded with electronic devices 20 to be tested at the first contact group 111, the second electronic device conveying medium 12 loaded with electronic devices 20 to be tested at the second contact group 112, and the third electronic device conveying medium 13 loaded with electronic devices 20 to be tested at the third contact group 113 are shown. Note that since the number of contact portions 110a is set to be zero in the fourth contact group 114, the electronic device conveying media 14 to be an object thereof is not shown in FIG. 14.

The electronic device conveying medium 11 and the electronic device conveying medium 12 aligned and supplied by the first electronic device conveying medium carrier CR1 are gripped by grip heads 201d of the first moving device 201 at a time and moved to the first range 301 above the first contact group 111 and the second contact group 112 by the first moving device 201.

Next, the first moving device 201 moves the electronic devices to be tested 20 on the first electronic device conveying medium 11 in FIG. 14 in a range from the first row on the first column to the second row on the fourth column to above the first contact group 111, and the electronic devices to be tested 20 on the second electronic device conveying medium 12 in a range from the first row on the first column to the second row on the fourth column to above the second contact group 112 together at a time.

Next, 8 electronic devices 20 in a range from the first row on the first column to the second row on the fourth column of an arrangement of the first electronic device conveying medium 11 is tested at the first contact group 111, and 8 electronic devices 20 in a range from the first row on the first column to the second row on the fourth column of an arrangement of the second electronic device conveying medium 12 is tested at the second contact group 112 by the first moving device 201 together at a time in the first round.

When the test is finished, the movable head 201c having grip heads 201d holding two electronic device conveying media, that is the first electronic device conveying medium 11 and the second electronic device conveying medium 12, is elevated by the first moving device 201, then, moved to the Y-axis direction by an amount of two rows.

Next, 8 electronic devices 20 in a range from the third row on the first column to the fourth row on the fourth column of an arrangement on the first electronic device conveying medium 11 are tested at the first contact group 111, and 8 electronic devices 20 in a range from the third row on the first column to the fourth row on the fourth column of an arrangement on the second electronic device conveying medium 12 are tested at the second contact group 112 together at a time in the second round by the first moving device 201.

Below, 8 electronic devices 20 are tested in the same order, and tests are conducted for four times in total.

After the tests for four times are completed, the post-tested first electronic device conveying medium 11 which comes first and the post-tested second electronic device conveying medium 12 which comes first are discharged to the post-test electronic device stocker 802 or the retest electronic device stocker 803 by the first electronic device conveying medium carrier CR1 via the third conveying means 403 of the unloader section UL, and the next electronic device conveying media 11 and 12 are supplied to the first moving device 201 by the first electronic device conveying medium carrier CR1.

The third electronic device conveying medium 13 aligned and supplied by the second electronic device conveying medium carrier CR2 is gripped by grip heads 202d of the second moving device 202 and moved to the second range 302 above the third contact group 113 and the fourth contact group 114 by the second moving device 202.

Next, electronic devices to be tested 20 in a range from the first row on the first column to the fourth row on the fourth column of the arrangement on the third electronic device conveying medium 13 in FIG. 14 are moved to above the third contact group 113.

Next, 16 electronic devices 20 in a range from the first row on the first column to the fourth row on the fourth column of the arrangement of the third electronic device conveying medium 13 are tested in the first round at the third contact group 113 by the second moving device 202.

When the test is finished, the movable head 202c having grip heads 202d holding the third electronic device conveying medium 13 is elevated by the second moving device 202, then, moved to the Y-axis direction by an amount of four rows.

Next, 16 electronic devices 20 in a range from the fifth row on the first column to the eighth row on the fourth column w of an arrangement on the third electronic device conveying medium 13 are tested in the second round at the third contact group 113 by the second moving device 202.

When the tests for two times in total are finished, the post-tested third electronic device conveying medium 13 which comes first is discharged to the post-test electronic device stocker 802 or the retest electronic device stocker 803 by the second electronic device conveying medium carrier CR2 via the third conveying means 403 of the unloader section UL, and the next third electronic device conveying medium 13 is supplied to the second moving device 202 by the second electronic device conveying medium carrier CR2.

Accordingly, the test is conducted for four times in total on one of first electronic device conveying media 11 and one of second electronic device conveying media 12, and the test is conducted for two times in total on one of third electronic device conveying media 13. Tests on two of third electronic device conveying media 13 can be finished before tests on one of first electronic device conveying media 11 and one of second electronic device conveying media 12 finish.

Note that test timing of the first moving device 201 and test timing of the second moving device 202 are synchronized by the main controller MC in the first moving device 201 and the second moving device 202, and tests are conducted at the same timing. By controlling the two moving devices 201 and 202 independently by the respective sub controllers SC1 and SC2, and securing 8 test positions in the first contact group 111, 8 test positions in the second contact group 112, and 16 test positions also in the third contact group 113, the simultaneously measured number of 32 limited in the electronic device testing apparatus 1 can be always secured and a high testing efficiency can be realized.

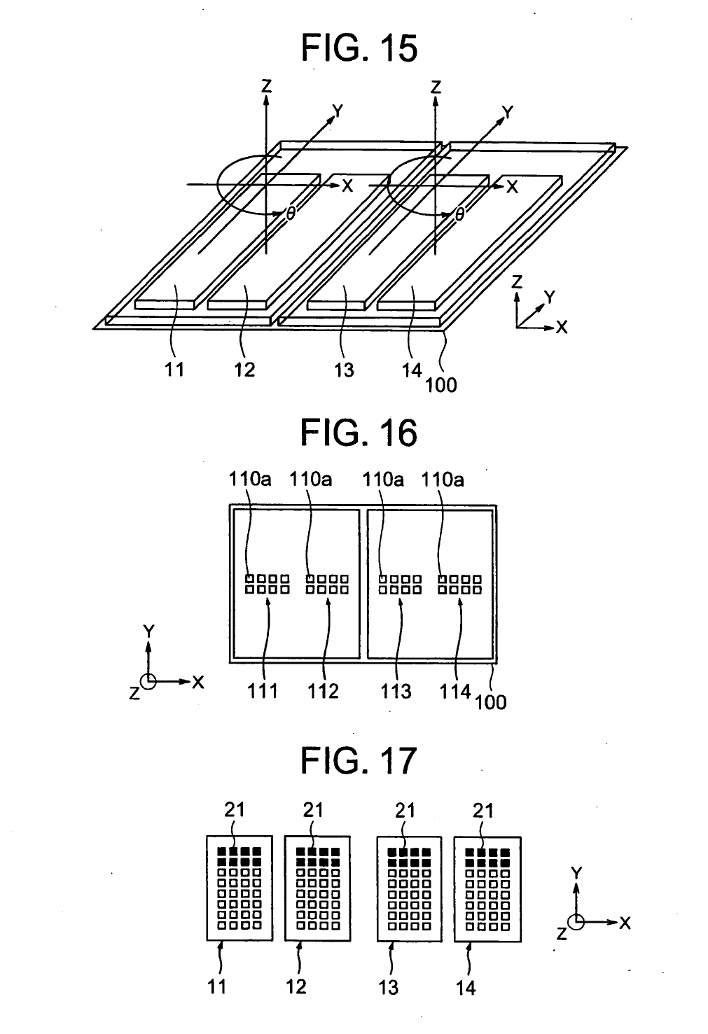

FIG. 15 shows a corresponding relationship of electronic device conveying media 11, 12, 13 and 14 and the respective contact groups 111, 112, 113 and 114 in an example in the case of four electronic device conveying media 11, 12, 13 and 14 loaded with electronic device to be tested 20. In this case, two electronic device conveying media 11 and 12 are gripped by the first moving device 201 having grip heads 201d capable of gripping two electronic device conveying media 11 and 12 at a time, and two electronic device conveying media 13 and 14 are gripped by the second moving device 202 having grip heads 202d capable of gripping two electronic device conveying media 13 and 14 at a time.

FIG. 16 shows an arrangement of the contact group 110 in the case of the simultaneously measured number of 32 corresponding to FIG. 15, wherein the number of contact portions 110a in the first contact group 111 is set to be 8 (two rows by four columns), the number of contact portions 110a in the second contact group 112 is also set to be 8 (two rows by four columns), the numbers of the contact portions 110a in the third contact group 113 is set to be 8 (two rows by four columns), and the number of contact portions 110a in the fourth contact group 114 is set to be 8 (two rows by four columns) for the four contact groups 111, 112, 113 and 114.

FIG. 16 shows the test positions 21 in the first round of an arrangement of electronic devices to be tested 20 on the electronic device conveying media 11, 12, 13 and 14 corresponding to FIG. 15, wherein the first electronic device conveying medium 11 loaded with electronic devices 20 to be tested at the first contact group 111, the second electronic device conveying medium 12 loaded with electronic devices 20 to be tested at the second contact group 112, the third electronic device conveying medium 13 loaded with electronic devices 20 to be tested at the third contact group 113, and the fourth electronic device conveying medium 14 loaded with electronic devices 20 to be tested at the fourth contact group 114 are shown.

The electronic device conveying medium 11 and the electronic device conveying medium 12 aligned and supplied by the first electronic device conveying medium carrier CR1 are gripped by grip heads 201d of the first moving device 201 at a time and moved to the first range 301 above the first contact group 111 and the second contact group 112 by the first moving device 201.

Next, the first moving device 201 moves the electronic devices to be tested 20 on the first electronic device conveying medium 11 in FIG. 17 in a range from the first row on the first column to the second row on the fourth column to above the first contact group 111, and the electronic devices to be tested 20 on the second electronic device conveying medium 12 in a range from the first row on the first column to the second row on the fourth column to above the second contact group 112 together at a time.

Next, 8 electronic devices 20 in a range from the first row on the first column to the second row on the fourth column of an arrangement of the first electronic device conveying medium 11 are tested at the first contact group 111, and 8 electronic devices 20 in a range from the first row on the first column to the second row on the fourth column of an arrangement of the second electronic device conveying medium 12 are tested at the second contact group 112 by the first moving device 201 together at a time in the first round.

When the test is finished, the movable head 201c having grip heads 201d holding two electronic device conveying media, that is the first electronic device conveying medium 11 and the second electronic device conveying medium 12, is elevated by the first moving device 201, then, moved to the Y-axis direction by an amount of two rows.

Next, 8 electronic devices 20 in a range from the third row on the first column to the fourth row on the fourth column of an arrangement on the first electronic device conveying medium 11 are tested at the first contact group 111, and 8 electronic devices 20 in a range from the third row on the first column to the fourth row on the fourth column of an arrangement on the second electronic device conveying medium 12 are tested at the second contact group 112 together at a time in the second round by the first moving device 201.

When the tests are finished, the movable head 201c having grip heads 201d holding two electronic device conveying media, that is the first electronic device conveying medium 11 and the second electronic device conveying medium 12, is elevated by the first moving device 201, then, moved to the Y-axis direction by an amount of two rows.

After that, the operation is repeated, and the test is conducted for four times in total on the two electronic device conveying media 11 and 12 by the first moving device 201.

After the tests for four times are completed, the post-tested first electronic device conveying medium 11 which comes first and the post-tested second electronic device conveying medium 12 which comes first are discharged to the post-test electronic device stocker 802 or the retest electronic device stocker 803 by the first electronic device conveying medium carrier CR1 via the third conveying means 403 of the unloader section UL, and the next electronic device conveying media 11 and 12 are supplied to the first moving device 201 by the first electronic device conveying medium carrier CR1.

The third electronic device conveying medium 13 aligned and supplied by the second electronic device conveying medium carrier CR2 is gripped by grip heads 202d of the second moving device 202 and moved to the second range 302 above the third contact group 113 and the fourth contact group 114 by the second moving device 202.

Next, electronic devices to be tested 20 in a range from the first row on the first column to the fourth row on the fourth column of the arrangement on the third electronic device conveying medium 13 in FIG. 17 are moved to above the third contact group 113, and electronic devices to be tested 20 in a range from the first row on the first column to the second row on the fourth column of the arrangement on the fourth electronic device conveying medium 14 are moved to above the fourth contact group 114 together at a time.

Next, 8 electronic devices 20 in a range from the first row on the first column to the second row on the fourth column of the arrangement of the third electronic device conveying medium 13 are tested at the third contact group 113, and 8 electronic devices 20 in a range from the first row on the first column to the second row on the fourth column of the arrangement of the fourth electronic device conveying medium 14 are tested at the fourth contact group 114 by the second moving device 202 together at a time in the first round.

When the test is finished, the movable head 202c having grip heads 202d holding the third electronic device conveying medium 13 and fourth electronic device conveying medium 14 are elevated by the second moving device 202, then, moved to the Y-axis direction by an amount of two rows.

Next, 8 electronic devices 20 in a range from the third row on the first column to the fourth row on the fourth column of an arrangement on the third electronic device conveying medium 13 are tested at the third contact group 113, and 8 electronic devices 20 in a range from the third row on the first column to the fourth row on the fourth column of an arrangement on the fourth electronic device conveying medium 14 are tested at the fourth contact group 114 by the second moving device 202 together at a time in the second round.

When the test is finished, the movable head 202c having grip heads 202d holding two electronic device conveying media, that is the third electronic device conveying medium 13 and fourth electronic device conveying medium 14, are elevated by the second moving device 202, then, moved to the Y-axis direction by an amount of two rows.

After that, the operation is repeated, and the tests are conducted for four times on the two electronic device conveying media 13 and 14 by the second moving device 202.

When the tests for four times in total are finished, the post-tested third electronic device conveying medium 13 which comes first and the post-tested fourth electronic device conveying medium 14 which comes first are discharged to the post-test electronic device stocker 802 and the retest electronic device stocker 803 by the second electronic device conveying medium carrier CR2 via the third conveying means 403 of the unloader section UL, and the next electronic device conveying media 13 and 14 are supplied to the second moving device 202 by the second electronic device conveying medium carrier CR2.

Accordingly, the test is conducted for four times in total on one of first electronic device conveying media 1, one of second electronic device conveying media 12, one of third electronic device conveying media 13 and one of fourth electronic device conveying media 14. Tests on one of second electronic device conveying media 12, one of third electronic device conveying media 13 and one of fourth electronic device conveying media 14 can be finished before tests on one of first electronic device conveying media 11 finish.

Note that test timing of the first moving device 201 and test timing of the second moving device 202 are synchronized by the main controller MC in the first moving device 201 and the second moving device 202, and tests are conducted at the same timing.

By controlling the two moving devices 201 and 202 independently by the respective sub controllers SC1 and SC2, and securing 8 test positions in the first contact group 111, 8 test positions in the second contact group 112, 8 test positions in the third contact group 113, and 8 test positions in the fourth conduct group 114, the simultaneously measured number of 32 limited in the electronic device testing apparatus 1 can be always secured and a high testing efficiency can be realized.

As explained above, by optimally determining the number of contact groups 110, the number and arrangement of contact portions 110a in the contact group 110 in accordance with an arrangement of electronic devices to be tested 20 on the electronic device conveying medium 10 and a production plan, etc., and optimally determining the number of mutually independent moving devices, contact groups corresponding to the respective moving devices, the number of electronic device conveying medium 10 able to be gripped by the respective moving devices, and the number of electronic device conveying media 10 gripped freely and independently from other moving devices within the number able to be gripped by the respective moving devices, the simultaneously measured number can be always secured while considering an occupying area, optimal facility costs, and optimal alignment accuracy, and a high testing efficiency can be realized.

Particularly, by combining the number of mutually independent moving devices, contact groups 110 corresponding to the respective moving devices, the number of electronic device conveying media able to be gripped by one moving device, and the number of electronic device conveying media 10 gripped freely and independently from other moving devices within the number able to be gripped by the respective moving devices, a conveying method can be flexibly matched to changes of circumstances, such as a production plan, in the same way as in the first embodiment.

Note that it is not limited to the test order of electronic devices to be tested on an electronic device conveying medium explained in the above first embodiment, and effective test orders of electronic devices to be tested on an electronic device conveying medium are included.

### Second Embodiment

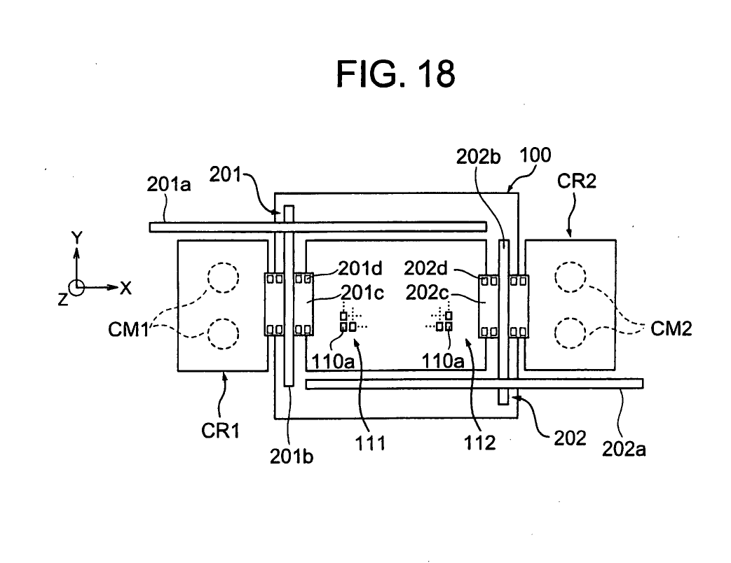

FIG. 18 is a schematic view of a test head portion 100 and a detailed configuration around it of an electronic device testing apparatus 1 of a second embodiment of the present invention.

The electronic device testing apparatus 1 of the present embodiment is an apparatus for testing (inspecting) whether electronic devices 20 suitably operate or not in a state of being applied with a thermal stress of a high temperature or a low temperature to the electronic devices to be tested 20 and classifying the electronic devices 20 in accordance with the test results. Such an operation test in a state of being applied with a thermal stress is conducted by conveying the electronic device conveying medium 10 loaded with the electronic devices to be tested 20 as test objects to inside the electronic device testing apparatus 1.

Note that the configuration of the electronic device testing apparatus 1 of the present embodiment is the same as that in the first embodiment except for the test head portion 100.

Test Head Portion 100

The electronic device conveying medium 10 is supplied to the test head portion 100 by the first electronic device conveying medium carrier CR1 or the second electronic device conveying medium carrier CR2, and the electronic devices to be tested 20 are subjected to a test while being loaded on the electronic device conveying medium 10.

The test head portion 100 comprises two contact groups, that is a first contact group 111 and a second contact group 112, for conducting a test on electronic devices to be tested 20 arranged on the electronic device conveying medium 10 supplied from the loader section LD; a first moving device 201 for controlling a position and posture of the electronic device conveying medium 10 loaded with electronic devices to be tested 20 in a first range 301 covering above the first contact group 111 and the second contact group 112 and a range including above the first electronic device conveying medium carrier CR1 above a first camera CM1; and a second moving device 202 for controlling a position and posture of the electronic device conveying medium 10 loaded with electronic devices to be tested 20 in a first range 301 covering above the first contact group 111 and the second contact group 112 and a range including above the second electronic device conveying medium carrier CR2 above a second camera CM2, namely, in a partially overlapping range with that of the first moving device 201.

Note that although the operation ranges of the two moving devices 201 and 202 partially overlap, they are controlled not to interfere with operations of the other.

The first moving device 201 is a means for controlling positions of a plurality of electronic device conveying media 10 (two electronic device conveying media in FIG. 18) in the X-Y-Z axes directions and controlling postures to the e-angle direction by using the Z-axis as a center axis. For example, it is configured to be movable in the first range 301 covering above the first contact group 111 and second contact group 112 and a range including the first electronic device conveying medium carrier CR1 above the first camera CM1 due to a rail 201a provided along the X-axis direction, a movable arm 201b moving on the rail 201a in the X-axis direction and a movable head 201c supported by the movable arm 201b and capable of moving in the Y-axis direction along the movable arm 201b.

The movable head 201c is movable also in the Z-axis direction (namely, in the vertical direction) by a not shown Z-axis actuator, furthermore, the θ-angle using the Z-axis as a center axis can be also controlled by a not shown posture control function. It is possible to grip, convey and release one or more electronic device conveying media 10 at a time by grip heads 201d (for example, 8 suction heads) provided to the movable head 201c.

One electronic device to be tested 20 on an electronic device conveying medium 10 corresponds to one contact 110a, and respective electronic devices to be tested 20 loaded on an electronic device conveying medium 10 gripped by grip heads 201d is applied a suitable pressure by an operation of the movable head 201c in the downward Z-axis direction and made to contact not shown contact pins on the contact 110a, so that a test is conducted. The test result is, for example, stored at an address determined by an identification number attached to an electronic device conveying medium 10 and an electronic device number assigned inside the electronic device conveying medium 10.

The first contact group 111 is composed of a set of contact portions 110a for conducting a test on electronic devices, and the second contact group 112 is also composed of a set of contact portions 110a in the same way. As far as the number of contact portions 110a in total in an electronic device testing apparatus 1 matches with the simultaneously measured number limited in the electronic device testing apparatus 1 (Normally, it is limited to 32 or 64), it is possible to determine optimal number of contact group and optimal number and arrangement of contact portions 110 in the respective contact groups in accordance with the number and arrangement of electronic devices to be tested 20 on the electronic device conveying medium 10.

Namely, as far as the total number of contact portions 110a of the first contact group 111 and second contact group 112 matches with the simultaneously measured number of 32 or 64 limited in the electronic device testing apparatus 1, the number of contact portions 110a in the respective contact groups 111 and 112 can be freely set.

Also, pitches between the respective contact portions 110a in the contact groups 111 and 112 have relationship of being identical with multiples of pitches (including 1) between respective electronic devices 20 arranged on electronic device conveying medium 10 corresponding to the respective contact groups 111 and 112.

As to the basic configuration and operation of the second moving device 202, it is a means for controlling positions of a plurality of electronic device conveying media 10 in the X-Y-Z axes directions and controlling a posture in the θ-angle direction using the Z-axis as a center axis and, for example, it is configured to be able to move in a first range 301 above the first contact group 111 and the second contact group 112 and a range including above the second electronic device conveying medium carrier CR2 above the second camera CM2 by a rail 202a provided along the X-axis direction, a movable arm 202b moving on the rail 202a in the X-axis direction, and a movable arm 202b supported by the movable arm 202b and movable along the movable arm 202b in the Y-axis direction in the same way as in the above first moving device 201.

The movable head 202c is movable in the Z-axis direction (that is, in the vertical direction) by a not shown Z-axis actuator and, furthermore, control of the θ-angle using the Z-axis as a center axis is also possible by a not shown posture control function. Also, one or more electronic device conveying media 10 can be gripped, conveyed and released at a time by grip heads 202d (for example, 8 suction heads) provided to the movable head 202c.

In the above example, the explanation was made in premise that there were two contact groups and two moving devices, and the number of electronic device conveying media 10 able to be gripped by the first moving device 201 and the second moving device 202 was two. But it is not limited to this and the number of contact groups 110, and the number and arrangement of contact portions 110a in contact groups 110 can be optimally determined (for example, one contact group 110 or three or more contact groups 110) in accordance with the number and arrangement of electronic devices to be tested 20 on the electronic device conveying medium 10 and a production plan, etc. The number of the mutually independent moving devices (for example, one moving device or three or more moving devices), contact groups 110 corresponding to the respective moving devices, the number of electronic device conveying media 10 able to be gripped by each moving device, the number of electronic device conveying media 10 gripped freely and independently from other moving devices within the number able to be gripped by the respective moving devices can be optimally set for each moving device.

Next, an operation will be explained. The electronic device conveying medium 10 loaded with electronic devices to be tested 20 aligned and supplied by the first electronic device conveying medium carrier CR1 is tested at the first contact group 111 and the second contact group 112 by the first moving device 201.

Also, the electronic device conveying medium 10 aligned and supplied by the second electronic device conveying medium carrier CR2 is tested at the first contact group 111 and the second contact group 112 by the second moving device 202.

In this case, the first moving device 201 and the second moving device 202 have partially overlapped operation ranges, but the operations are controlled not to interfere with each other.

Below, as shown in FIG. 18, a specific testing method will be explained in the case of the simultaneously measured number of 32 using the electronic device testing apparatus 1, wherein two electronic device conveying media 11 and 12 are gripped by the first moving device 201 having grip heads 201d capable of gripping two electronic device conveying media 11 and 12, and two electronic device conveying media 11 and 12 are gripped by the second moving device 202 having grip heads 202d capable of gripping two electronic device conveying media 11 and 12.

Note that the electronic device conveying medium 11 indicates an electronic device conveying medium loaded with electronic devices 20 to be tested at the first contact group 111 and the electronic device conveying medium 12 indicates an electronic device conveying medium loaded with electronic devices 20 to be tested at the second contact group 112 below.

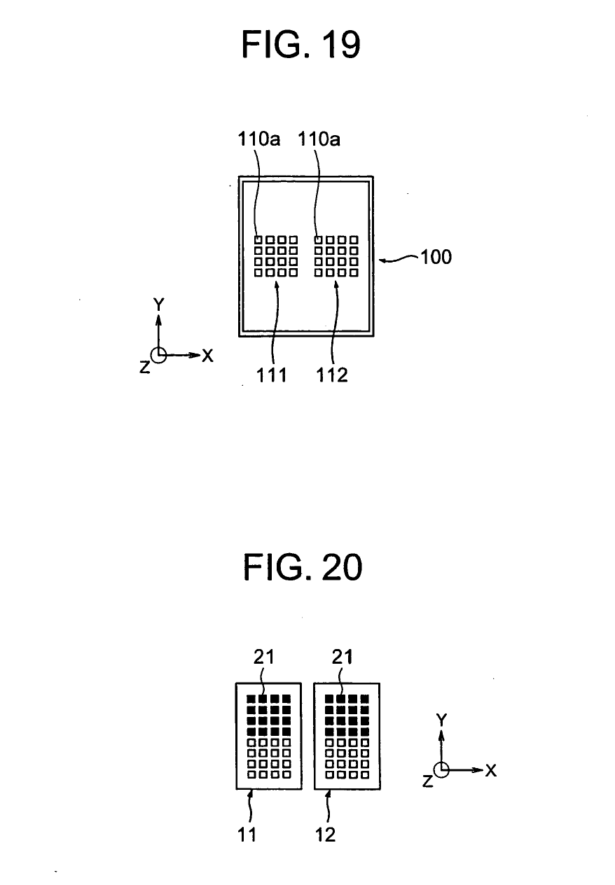

FIG. 19 shows an arrangement of contact groups 110 in the case of the simultaneously measured number of 32 corresponding to FIG. 18, wherein the number of contact portions 110a in the first contact group 111 is set to be 16 (four rows by four columns) and the number of contact portions 110a in the second contact group 112 is set to be 16 (four rows by four columns).

FIG. 20 shows test positions 21 in the first round on electronic devices to be tested 20 arranged on the electronic device conveying medium 11 corresponding to FIG. 19, wherein the first electronic device conveying medium 11 loaded with electronic devices 20 to be tested at the first contact group 111 and the second electronic device conveying medium 12 loaded with electronic devices 20 to be tested at the second contact group 112 are shown.

Two electronic device conveying media, that is the first electronic device conveying medium 11 which comes first and the second electronic device conveying medium 12 which comes first, aligned and supplied by the first electronic device conveying medium carrier CR1 are gripped by grip heads 201d of the first moving device 201 at a time and moved to the first range 301 above the first contact group 111 and the second contact group 112 by the first moving device 201.

Next, the first moving device 201 moves electronic devices to be tested 20 in a range from the first row on the first column to the fourth row on the fourth column of the arrangement on the first electronic device conveying medium 11 in FIG. 20 to above the first contact group 111, and moves electronic devices to be tested 20 in a range from the first row on the first column to the fourth row on the fourth column of the arrangement on the second electronic device conveying medium 12 to above the second contact group 112 together at a time.

Next, the first moving device 201 conducts a test in the first round on 16 electronic devices 20 in a range from the first row on the first column to the fourth row on the fourth column on the arrangement of the first electronic device conveying medium 11 and 16 electronic devices 20 in a range from the first row on the first column to the fourth row on the fourth column on the arrangement of the second electronic device conveying medium 12 together at a time.

When the test is finished, the movable head 201c having grip heads 201d holding the first electronic device conveying medium 11 and the second electronic device conveying medium 12 is elevated by the first moving device 201, then, moved to the Y-axis direction by an amount of four rows.

Next, the first moving device 201 conducts a test in the second round on 16 electronic devices 20 in a range from the fifth row on the first column to the eighth row on the fourth column on the arrangement of the first electronic device conveying medium 11 and 16 electronic devices 20 in a range from the fifth row on the first column to the eighth row on the fourth column on the arrangement of the second electronic device conveying medium 12 together at a time, so that the test is conducted for two times in total.

Accordingly, the test is conducted for two times on the first electronic device conveying medium 11 which comes first and the second electronic device conveying medium 12 which comes first together at a time.

While the above first moving device 201 conducts a test for two times in total, a first electronic device conveying medium 11 which comes second and a second electronic device conveying medium 12 which comes second are supplied from the buffer portion 901 to the second electronic device conveying medium carrier CR2 via the second conveying means 402, and the second electronic device conveying medium carrier CR2 moves to above the second camera CM2, consequently, supply of the first electronic device conveying medium 11 which comes second and the second electronic device conveying medium 12 which comes second to the second moving device 202 is prepared.

After the tests for two times in total on the first electronic device conveying medium 11 which comes first and the second electronic device conveying medium 12 which comes first are finished, the post-test first electronic device conveying medium 11 which comes first and the post-test second electronic device conveying medium 12 which comes first are discharged to the post-test electronic device stocker 802 or the retest electronic device stocker 803 by the first electronic device conveying medium carrier CR1 via the third conveying means 403 of the unloader section UL, and the electronic device conveying media 11 and 12 which come second prepared by the second electronic device conveying medium carrier CR2 are supplied.

Next, two electronic device conveying media, that is the first electronic device conveying medium 11 which comes second and the second electronic device conveying medium 12 which comes second, aligned and supplied by the second electronic device conveying medium carrier CR2 are gripped by grip heads 202d of the second moving device 202 at a time and moved to the first range 301 above the first contact group 111 and the second contact group 112 by the second moving device 202.

Next, the second moving device 202 moves electronic devices to be tested 20 in a range from the first row on the first column to the fourth row on the fourth column of the arrangement on the first electronic device conveying medium 11 in FIG. 20 to above the first contact group 111, and moves electronic devices to be tested 20 in a range from the first row on the first column to the fourth row on the fourth column on the second electronic device conveying medium 12 to above the second contact group 112 together at a time.

Next, the second moving device 202 conducts a test in the first round on 16 electronic devices 20 in a range from the first row on the first column to the fourth row on the fourth column on the arrangement of the first electronic device conveying medium 11 and 16 electronic devices 20 in a range from the first row on the first column to the fourth row on the fourth column on the arrangement of the second electronic device conveying medium 12 together at a time.

When the test is finished, the movable head 202c having grip heads 202d holding the first electronic device conveying medium 11 and the second electronic device conveying medium 12 is elevated by the second moving device 202, then, moved to the Y-axis direction by an amount of four rows.

Next, the second moving device 202 conducts a test in the second round on 16 electronic devices 20 in a range from the fifth row on the first column to the eighth row on the fourth column on the arrangement of the first electronic device conveying medium 11 and 16 electronic devices 20 in a range from the fifth row on the first column to the eighth row on the fourth column on the arrangement of the second electronic device conveying medium 12 together at a time, so that the test is conducted for two times in total.

Accordingly, the test is conducted for two times on the first electronic device conveying medium 11 which comes second and the second electronic device conveying medium 12 which comes second at a time.

While the above second moving device 202 conducts a test for two times in total, a first electronic device conveying medium 11 which comes third and a second electronic device conveying medium 12 which comes third are supplied from the buffer portion 901 to the first electronic device conveying medium carrier CR1 via the second conveying means 402, and the first electronic device conveying medium carrier CR1 moves to above the first camera CM1, consequently, supply of the first electronic device conveying medium 11 which comes third and the second electronic device conveying medium 12 which comes third to the first moving device 201 is prepared.

After the tests for two times in total on the first electronic device conveying medium 11 which comes second and the second electronic device conveying medium 12 which comes second are finished, the post-test first electronic device conveying medium 11 which comes second and the post-test second electronic device conveying medium 12 which comes second are discharged to the post-test electronic device stocker 802 or the retest electronic device stocker 803 by the second electronic device conveying medium carrier CR2 via the third conveying means 403 of the unloader section UL, and the electronic device conveying media 11 and 12 which come third prepared by the first electronic device conveying medium carrier CR1 are supplied.

After that, the above operation by the first moving device 201 and the second moving device 202 are repeated alternately.

As explained above, by securing 16 test positions in the first contact group 111 and securing 16 test positions also in the second contact group 112, it is possible to always secure the simultaneously measured number of 32 limited in the electronic device testing apparatus 1 and a high testing efficiency can be realized.

Furthermore, as a result that the first moving device 201 and the second moving device 202 operate alternately on the same first range 301, index time occupying a part of the test rate of one moving device (the shortest time from an output of a start request signal by the handler side to an output of the next start request signal) can be absorbed in the test time of the other moving device. Particularly, when the test time is short, since the ratio occupied by the index time in the test rate becomes large, high throughput can be realized by conducting a test in turn by a plurality of moving devices on a range wherein the contact group 110 exists as in the above example.

Note that in the second embodiment, the explanation was made on the two contact groups 111 and 112, two moving devices 201 and 202 movable in the first range 301 covering above the two contact groups 111, 112 and capable of gripping two electronic device conveying media and independently controllable, and two electronic device conveying medium carriers CR1 and CR2 for independently supplying an electronic device conveying medium 10 to the respective moving devices. But it is not limited to these numbers and includes an electronic device testing apparatus comprising two or more contact groups 110 and two or more moving devices capable of gripping two or more electronic device conveying media respectively and controlling independently, and having the two or more moving devices having a substantially overlapping operation range on any one of contact groups.

Also, it is not limited to the test order of electronic devices to be tested on the electronic device conveying medium explained in the above second embodiment, and includes effective test orders of electronic devices to be tested on the electronic device conveying medium.

### Third Embodiment

In a test on electronic devices 20 on the wafers 701 and 702, there are a few cases where test positions by the simultaneously measured number can be always secured in measurement on electronic devices 20 near the outer circumference of the wafer 701 and 702, and only less test positions than the simultaneously measured number can be secured under present circumstances.

The present invention can be applied not only to the case of testing an electronic device conveying medium 10, such as a strip format, described in the first embodiment and the second embodiment, but to the case of testing electronic devices 20 on the wafers 701 and 702, and is effective for securing test positions by the simultaneously measured number.

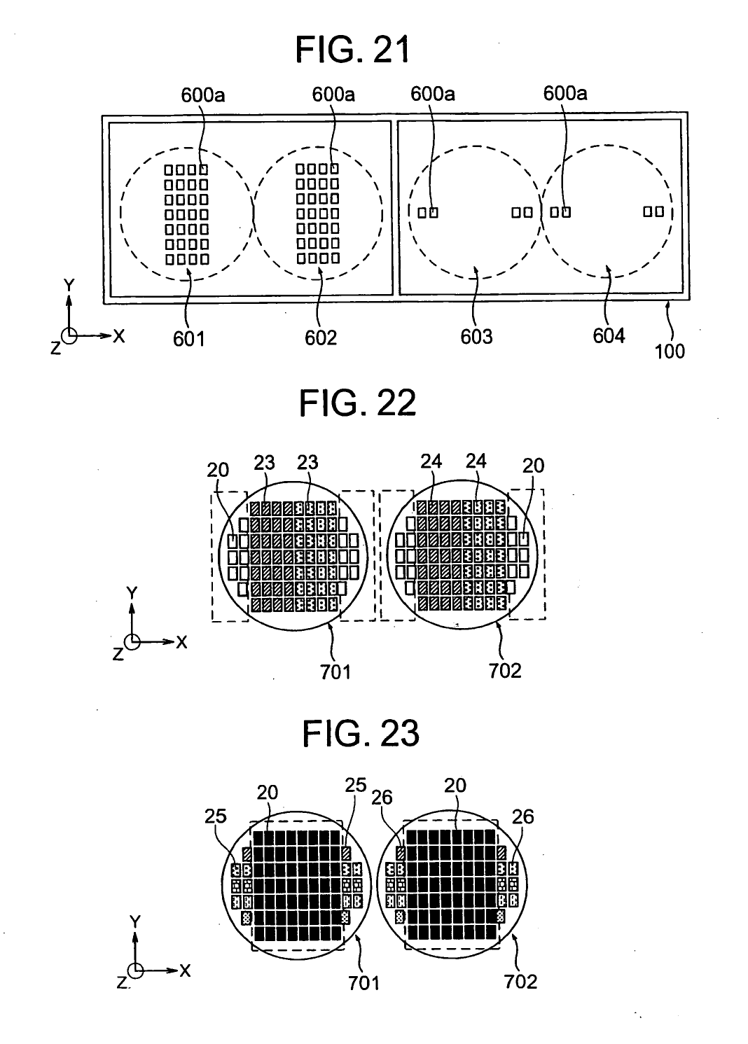

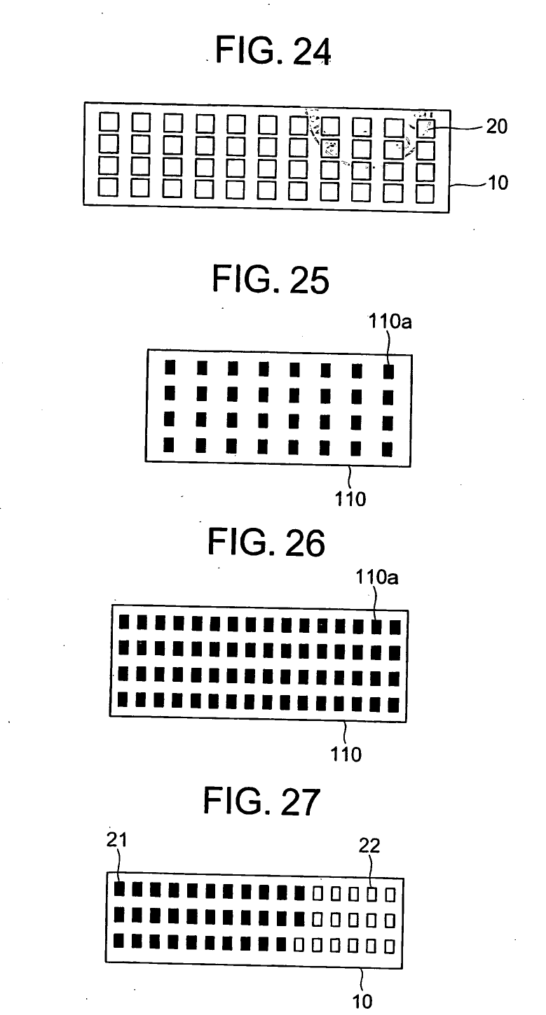

As shown in FIG. 21, the test head portion 100 comprises four prober groups: a first prober group 601 and second prober group 602 having 28 probers 600a, and a third prober group 603 and fourth prober group 604 having 4 probers 600a, and the simultaneously measured number in this case is 64.

Note that the prober groups 601, 602, 603 and 604 are composed of a set of probers 600a for conducting a test on electronic devices to be tested 20 on the wafers 701 and 702.

Among respectively 72 electronic devices to be tested 20 (note that there is not an electronic device 20 near the outer circumferential portion: at the first row on the first column, the first row on the second column, the first row on the eleventh column, the first row on the twelfth column, the second row on the first column, the second row on the twelfth column, the sixth row on the first column, the sixth row on the twelfth column, the seventh row on the first column, the seventh row on the second column, the seventh row on the eleventh column, and the seventh row on the twelfth column) in arrangement of the seven rows by twelve columns on the first wafer 701 and second wafer 702 supplied from a loader section (not shown), 28 electronic devices 20 in a range from the first row on the third column to the seventh row on the sixth column at the first wafer 701 in the first prober group 601 and 28 electronic devices 20 in the range from the first row on the third column to the seventh row on the sixth column on the second wafer 702 at the second prober group 602 as shown in FIG. 22 are tested in the first round together at a time.

When the test is finished, a movable head (not shown) having grip heads holding the two wafers 701 and 702 at a time is elevated, then, moved to the X-axis direction by an amount of four columns.

Next, 28 electronic devices 20 in a range from the first row on the seventh column to the seventh row on the tenth column on the first wafer 701 are tested at the first prober group 601, and 28 electronic devices 20 in a range from the first row on the seventh column to the seventh row on the tenth column on the second wafer 702 are tested at the second prober group 602 together at a time in the second round. Tests on 56 electronic devices 20 in total as test positions 23 and 24 (the test positions 23 and 24 in the first prober group 601 and the second prober group 602 are sets of squares with a pattern in FIG. 22) in the first prober group 601 and the second prober group 602 are completed by two-round tests in total, and the two wafers 701 and 702 are given to the third prober group 603 and the fourth prober group 604.

Note that it is not limited to a method of giving the two wafers 701 and 702 finished with the test at the first prober group 601 and the second prober group 602 to the third prober group 603 and the fourth prober group 604, but a method of giving to loader sections being independent to the respective prober groups may be considered.

After finishing the test in the first prober group 601 and the second prober group 602, the two wafers 701 and 702 are moved to the third prober group 603 and the fourth prober group 604, two electronic devices 20 at the second row on the second column and at the second row on the eleventh column on the first wafer 701 are tested at the third prober group 603, and two electronic devices 20 on the second row on the second column and on the second row on the eleventh column on the second wafer 702 are tested at the fourth prober group 604 together at a time in the first round.

When the test is finished, a movable head (not shown) holding the two wafers 701 and 702 is elevated, then, moved to the Y-axis direction by an amount of one row.

Next, four electronic devices 20 at the third line on the first row, at the third line on the second row, at the third line on the eleventh row and at the third line on the twelfth row on the first wafer 701 are tested at the third prober group 603, and four electronic devices 20 at the third line on the first row, at the third line on the two row, at the third line on the eleventh row and at the third line on the twelfth row on the second wafer 702 are tested at the fourth prober group 604 together at a time in the second round.

When the test is finished, a movable head holding the two wafers 701 and 702 is elevated, then, moved to the Y-axis direction by an amount of one row.

Next, four electronic devices 20 at the fourth row on the first column, at the fourth row on the second column, at the fourth row on the eleventh column and at the fourth row on the twelfth column on the first wafer 701 are tested at the third prober group 603, and four electronic devices 20 at the fourth row on the first column, at the fourth row on the second column, at the fourth row on the eleventh column and at the fourth row on the twelfth column on the second wafer 702 are tested at the fourth prober group 604 together at a time in the third round.

When the test is finished, a movable head holding the two wafers 701 and 702 is elevated, then, moved to the Y-axis direction by an amount of one row.

Next, four electronic devices 20 at the fifth row on the first column, at the fifth row on the second column, at the fifth row on the eleventh column and at the fifth row on the twelfth column on the first wafer 701 are tested at the third prober group 603, and four electronic devices 20 at the fifth row on the first column, at the fifth row on the second column, at the fifth row on the eleventh column and at the fifth row on the twelfth column on the second wafer 702 are tested at the fourth prober group 604 together at a time in the third round.

When the test is finished, a movable head holding the two wafers 701 and 702 is elevated, then, moved to the Y-axis direction by an amount of one row.

Next, two electronic devices 20 at the sixth row on the second column and at the sixth row on the eleventh column on the first wafer 701 are tested at the third prober group 603, and two electronic devices 20 at the sixth row on the second column and at the sixth row on the eleventh column on the second wafer 702 are tested at the fourth prober group 604 together at a time. Tests on 16 electronic devices 20 in total as test positions 25 and 26 (the test positions 25 and 26 in the third prober group 603 and the fourth prober group 604 are sets of squares with a pattern in FIG. 23) in the third prober group 603 and the fourth prober group 604 are completed by five rounds in total.

After finishing the test in the third prober group 603 and the fourth prober group 604, the two wafers 701 and 702 are given to the unloader section (not shown), and next wafers 701 and 702 are supplied from the first prober group 601 and the second prober group 602 or from loader sections being independent for respective prober groups.

Note that test timing in the first prober group 601 and second prober group 602 and test timing in the third prober group 603 and fourth prober group 604 are synchronized in the respective moving devices by the main controller MC (not shown), and the tests are conducted at the same timing.

As explained above, when conducting a test on electronic devices 20 on the wafers 701 and 702, by dividing to the first prober 601 and the second prober group 602 for testing on the electronic devices 20 existing at the center of the wafers 701 and 702 and to the third prober group 603 and the fourth prober group 604 for testing on the electronic devices 20 existing near the outer circumference, test positions close to the simultaneously measured number of 64 can be secured, and a high test efficiency can be realized in a test on electronic devices to be tested 20 on the wafers 701 and 702 near the outer circumference where test positions by the simultaneously measured number can be hardly secured.

Note that in the above embodiment, a method of gripping a wafer by grip heads and moving a movable head having the grip heads was applied, but it is not limited to this method and, for example, a method of fixing the wafer and performing alignment control on prober groups with respect to the electronic devices may be also considered.

Note that in the third embodiment, four prober groups 601, 602, 603 and 604, and a moving device capable of gripping two wafers 701 and 702 were explained, but the numbers are not limited to these, and an electronic device testing apparatus comprising one to three prober groups or five or more prober groups, and a moving device capable of gripping two or more wafers is included. It is not limited to the test order of electronic devices to be tested on the electronic device conveying medium explained in the third embodiment, and effective test orders of electronic devices to be tested on the electronic device conveying medium are included.

Note that the embodiments explained above are described to facilitate understanding of the present invention and is not to limit the present invention. Accordingly, respective elements disclosed in the above embodiments include all design modifications and equivalents belonging to the technical scope of the present invention.

For example, in the case of the first embodiment, other than the method of covering the whole test head portion 100 with a chamber for conducting a test in a state of applying a thermal stress, a method of applying a heat plate to the buffer portion and other methods may be considered, and the electronic device testing apparatus of the present invention includes them.

Note that the simultaneously measured numbers in the embodiments of the present invention are not limited to the above numbers and may be applied to simultaneously measured numbers of 2ⁿ.

1. An electronic device testing apparatus, for conducting a test by pressing input/output terminals of electronic devices to be tested against contact portions of a test head by a moving means while said electronic devices to be tested are loaded on an electronic device conveying medium, comprising:
one or a plurality of said moving means capable of gripping and conveying to and from said contact portions a plurality of said electronic device conveying media loaded with said electronic devices to be tested at a time.

2. The electronic device testing apparatus as set forth in claim 1, wherein said moving means is capable of freely selecting the gripping number within the number able to be gripped.

3. The electronic device testing apparatus as set forth in claim 1, wherein said one moving means is capable of freely selecting the gripping number being independent from other moving means.

4. The electronic device testing apparatus as set forth in claim 1, wherein said any two or more moving means among said plurality of moving means have a substantially overlapping operation range on a contact group as a set of said contact portions.

5. The electronic device testing apparatus as set forth in any one of claims 1 to 4, wherein said electronic device conveying medium is a strip format or a wafer.

6. The electronic device testing apparatus as set forth in any one of claims 1 to 4, wherein each of said moving means grips said electronic device conveying medium loaded with said electronic devices to be tested and moves from a loading position of pre-test electronic devices to said contact portions.

7. The electronic device testing apparatus as set forth in any one of claims 1 to 4, wherein each of said moving means grips said electronic device conveying medium loaded with said electronic devices to be tested and moves from said contact portions to a loading position of post-test electronic devices.

8. The electronic device testing apparatus as set forth in any one of claims 1 to 4, wherein a sum of the numbers of contact portions in said test head is 2ⁿ (“n” is a natural number).

9. The electronic device testing apparatus as set forth in claim 8, wherein n=5.

10. The electronic device testing apparatus as set forth in claim 8, wherein n=6.
